(19) United States
(12) Patent Application Publication
(10) Pub. No.: US 2025/0116940 A1
(43) Pub. Date: Apr. 10, 2025

(54) IMAGING EUV OPTICAL UNIT FOR IMAGING AN OBJECT FIELD INTO AN IMAGE FIELD

(71) Applicant: Carl Zeiss SMT GmbH, Oberkochen (DE)

(72) Inventor: Markus SCHWAB, Aalen (DE)

(21) Appl. No.: 18/984,649

(22) Filed: Dec. 17, 2024

Related U.S. Application Data
(63) Continuation of application No. PCT/EP2023/065623, filed on Jun. 12, 2023.

(30) Foreign Application Priority Data
Jun. 20, 2022 (DE) 10 2022 206 110.1

(51) Int. Cl. G03F 7/00

(52) U.S. Cl. CPC G03F 7/70233; G03F 7/70033

(57) ABSTRACT

An imaging EUV optical unit serves for imaging an object field into an image field. The optical unit has a plurality of mirrors for guiding EUV imaging light at a wavelength shorter than 30 nm along an imaging beam path from the object field to the image field. The plurality of the mirrors includes at least two normal incidence mirrors and at least two grazing incidence mirrors. An overall transmission of the plurality of the mirrors is greater than 10%. This yields an imaging EUV optical unit whose usability for an EUV projection exposure apparatus can be improved.

### CROSS-REFERENCE TO RELATED APPLICATIONS

The present application is a continuation of, and claims benefit under 35 USC 120 to, international application No. PCT/EP2023/065623, filed Jan. 17, 2023, which claims benefit under 35 USC 119 of German Application No. 10 2022 206 110.1, filed Jun. 20, 2022. The entire disclosure of each of these applications is incorporated by reference herein.

### FIELD

The disclosure relates to an imaging EUV optical unit for imaging an object field into an image field. Furthermore, the disclosure relates to an optical system having such an imaging optical unit, a projection exposure apparatus having such an optical system, a method for producing a microstructured or nanostructured component by such a projection exposure apparatus, and a microstructured or nanostructured component produced by the method.

### BACKGROUND

Projection optical units are known from WO 2018/010960 A1, from DE 10 2015 209 827 A1, from DE 10 2012 212 753 A1, from US 2010/0149509 A1 and from U.S. Pat. No. 4,964,706. The specialist article “Polarization dependence of multilayer reflectance in the EUV spectral range” by F. Scholze et al., Proc. of SPIE, Vol. 6151 615137-1 to -8, discloses reflection data measured via an EUV reflectometer. DE 10 2011 075 579 A1 discloses a mirror and a microlithographic projection exposure apparatus having such a mirror. DE 10 2015 226 529 A1 discloses an imaging optical unit for imaging an object field into an image field and a projection exposure apparatus having such an imaging optical unit.

### SUMMARY

The present disclosure seeks to develop an imaging EUV optical unit with improved usability in an EUV projection exposure apparatus.

The disclosure provides an imaging EUV optical unit for imaging an object field into an image field. The unit includes a plurality of mirrors for guiding EUV imaging light at a wavelength shorter than 30 nm along an imaging beam path from the object field to the image field. The plurality of mirrors includes at least two normal incidence (NI) mirrors and at least two grazing incidence (GI) mirrors. A total transmission of the plurality of mirrors is greater than 10%.

According to the disclosure, it was recognized that the use of at least two NI mirrors and at least two GI mirrors within the imaging EUV optical unit can render designs accessible which can have a surprisingly high total transmission of more than 10%. For a given EUV used light source power, a total transmission of more than 10% allows an increased EUV throughput to the image field, and hence an improved exposure power.

Alternatively, for a given, exposure power used on the image field, it is possible to use a reduced power source.

The imaging EUV optical unit may comprise at least four GI mirrors.

The total or overall transmission of the imaging EUV optical unit may be greater than 11%, may be greater than 12%, may be greater than 13%, may be greater than 14% and may also be greater than 15%. The overall transmission of the imaging EUV optical unit may be at least 11.8%. The overall transmission is regularly less than 20% on account of the number of mirrors and on account of an individual transmission of an imaging light-guiding mirror which is regularly no more than 80%.

The imaging EUV optical unit may have an image-side numerical aperture of less than 0.5 and, for example, less than 0.4. The image-side numerical aperture may be greater than 0.25 and may be greater than 0.3.

A mean wavefront aberration RMS may be less than 200 mλ (λ: wavelength of the used light), may be less than 100 mλ and may also be less than 50 mλ. This wavefront aberration RMS is regularly greater than 5 mλ.

The object field of the imaging EUV optical unit may be located in an object plane. The image field of the imaging EUV optical unit may be located in an image plane. The object plane may extend parallel to the image plane. The object plane may extend relative to the image plane at an angle which differs from 0°.

The last two mirrors in the imaging beam path can be NI mirrors. This can allow the use of a last mirror upstream of the image field, the mirror specifying an image-side numerical aperture that is as large as possible by way of comparatively small angles of incidence present there and by way of its mirror dimension.

The imaging optical unit can comprise exactly two NI mirrors, and/or the imaging optical unit can comprise exactly four GI mirrors or exactly five GI mirrors or exactly six GI mirrors. Such arrangements were found to provide a combination of high overall transmission and a good imaging quality at the same time.

The imaging optical unit can comprise at least one pair of successive GI mirrors which add in terms of their deflective effect. Such mirror pairs were found to complement one another well in terms of their beam shaping effect. For example, the imaging EUV optical unit may comprise two such GI mirror pairs, the deflective effect of which counters one another such that the deflective effect of the second GI mirror pair has a subtractive effect in relation to the deflective effect of the first GI mirror pair. What can be achieved overall as a result is that a total deflective effect of the NI mirrors on the imaging light is comparatively small, with the result that designs where an angle between an object plane and an image plane is small and where the object plane can extend parallel to the image plane remain accessible.

Two imaging beam path sections can cross in a crossing region between respectively two successive mirrors and/or between a mirror and a field of the EUV optical unit. Such embodiments can enable a distribution of angles of incidence on the mirrors of the imaging EUV optical unit which is reflectivity-optimized, in particular in respect of the absolute angles of incidence on the mirror surfaces and/or in respect of the smallest possible angle of incidence bandwidths on the mirrors. Such an embodiment, for example, ensures a highly reflective coating of the mirrors. Alternatively, no such crossing region may be present in the case of the imaging EUV optical unit.

The two crossing imaging beam path sections can be: i) an imaging beam path section between a mirror upstream of the penultimate NI mirror in the imaging beam path and the penultimate mirror in the imaging beam path; and ii) an imaging beam path section between the last mirror in the imaging beam path and the image field. This can allow small angles of incidence on the penultimate NI mirror.

An entrance pupil in the imaging beam path can be upstream of the object field. This can allow the use of an illumination optical unit in the imaging light beam path upstream of the object field, in the case of which a mirror of the illumination optical unit arranged in the entrance pupil is the last EUV light-guiding mirror upstream of the object field. Reflectivity losses due to an interposed transfer optical unit, desired in other cases, are cancelled.

Related optical systems projection exposure apparatus, production method and nanostructured component can have features corresponding to those which have already been explained above with reference to the projection optical unit according to the disclosure. Alternative illumination light input coupling is possible in a related optical system, which may satisfy corresponding installation space limitations.

The EUV light source of a projection exposure apparatus can be embodied in such a way that a used wavelength emerges which is no more than 13.5 nm, which is less than 13.5 nm, which is less than 10 nm, which is less than 8 nm, which is less than 7 nm and which is 6.7 nm or 6.9 nm, for example. A used wavelength of less than 6.7 nm and, for example, of the order of 6 nm is also possible.

For example, a semiconductor component, for example a memory chip, can be produced using the projection exposure apparatus.

### BRIEF DESCRIPTION OF THE DRAWINGS

Below, exemplary embodiments of the disclosure is described on the basis of the drawings, in which:

FIG. 1 schematically shows a meridional section of a projection exposure apparatus for EUV projection lithography;

FIGS. 2-7 show, in each case in a meridional section, embodiments of an imaging optical unit which is used as a projection lens in the projection exposure apparatus according to FIG. 1, wherein an imaging beam path for chief rays and for an upper coma ray and a lower coma ray of three selected field points is depicted.

### DETAILED DESCRIPTION

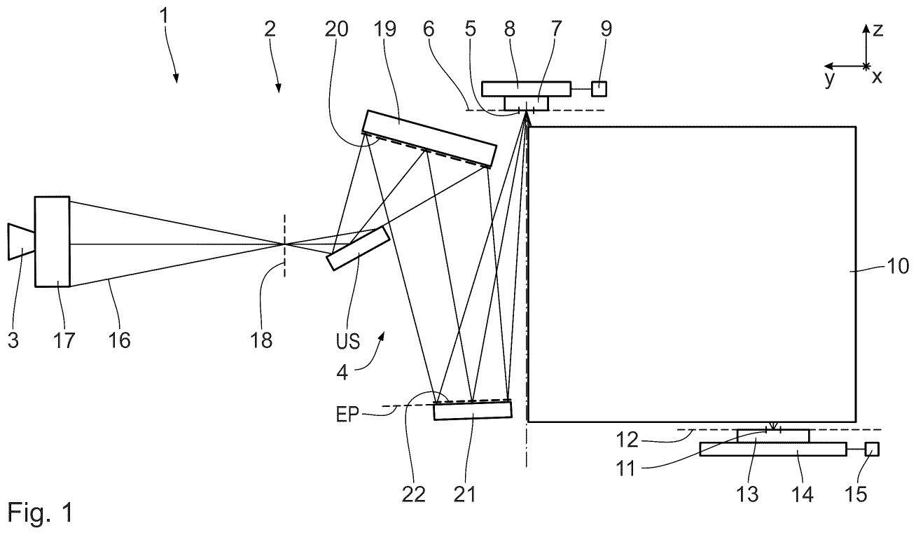

In the following text, certain components of a microlithographic projection exposure apparatus 1 are described first by way of example with reference to FIG. 1. The description of the basic structure of the projection exposure apparatus 1 and its components should not be construed as limiting here.

An embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is exposed. The reticle 7 is held by a reticle holder 8. The reticle holder 8 is displaceable, in particular in a scanning direction, by way of a reticle displacement drive 9.

A Cartesian xyz-coordinate system is shown in FIG. 1 for explanation purposes. The x-direction runs perpendicular to the plane of the drawing into the latter. The y-direction runs horizontally, and the z-direction runs vertically. The scanning direction runs in the y-direction in FIG. 1. The z-direction runs perpendicularly to the object plane 6.

The projection exposure apparatus 1 comprises a projection optical unit or imaging optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable, in particular in the y-direction, by way of a wafer displacement drive 15. The displacement on the one hand of the reticle 7 by way of the reticle displacement drive 9 and on the other hand of the wafer 13 by way of the wafer displacement drive 15 may take place in such a way as to be synchronized with one another.

The radiation source 3 is an EUV radiation source. The radiation source 3 emits EUV radiation 16 in particular, which is also referred to below as used radiation or illumination radiation. In particular, the used radiation has a wavelength in the range of between 5 nm and 30 nm. The radiation source 3 can be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emerging from the radiation source 3 is focused by a collector 17. The collector 17 may be a collector with one or more ellipsoidal and/or hyperboloidal reflection surfaces. The illumination radiation 16 can be incident on the at least one reflection surface of the collector 17 with grazing incidence (GI), that is to say at angles of incidence of greater than 45°, or with normal incidence (NI), that is to say at angles of incidence of less than 45°. The collector 17 can be structured and/or coated firstly for optimizing its reflectivity for the used radiation and secondly for suppressing stray light.

Downstream of the collector 17, the illumination radiation 16 propagates through an intermediate focus in an intermediate focal plane 18. The intermediate focal plane 18 can represent a separation between a radiation source module, comprising the radiation source 3 and the collector 17, and the illumination optical unit 4.

The illumination optical unit 4 comprises a first facet mirror 19. If the first facet mirror 19 is arranged in a plane of the illumination optical unit 4 which is optically conjugate to the object plane 6, then this facet mirror is also referred to as a field facet mirror. The first facet mirror 19 comprises a multiplicity of individual first facets 20, which are also referred to as field facets below. Only a few of these facets are illustrated in FIG. 1 in exemplary fashion.

The first facets 20 may be embodied as macroscopic facets, in particular as rectangular facets or as facets with an arcuate edge contour or an edge contour of part of a circle. The first facets 20 may be embodied as plane facets or alternatively as facets with convex or concave curvature.

As known for example from DE 10 2008 009 600 A1, the first facets 20 themselves can also be composed in each case of a multiplicity of individual mirrors, in particular a multiplicity of micromirrors. The first facet mirror 19 may in particular be formed as a microelectromechanical system (MEMS system). For details, reference is made to DE 10 2008 009 600 A1.

A deflection mirror US, which may be embodied as a plane mirror but which may alternatively also have a beam shaping effect, is located in the beam path of the illumination optical unit 4, between the intermediate focus in the intermediate focal plane 18 and the first facet mirror 19.

In the beam path of the illumination optical unit 4, a second facet mirror 21 is arranged downstream of the first facet mirror 19. If the second facet mirror 21 is arranged in a pupil plane of the illumination optical unit 4, it is also referred to as a pupil facet mirror. The second facet mirror 21 can also be arranged at a distance from a pupil plane of the illumination optical unit 4. In this case, the combination of the first facet mirror 19 and the second facet mirror 21 is also referred to as a specular reflector. Specular reflectors are known from US 2006/0132747 A1, EP 1 614 008 B1, and U.S. Pat. No. 6,573,978.

The second facet mirror 21 comprises a plurality of second facets 22. In the case of a pupil facet mirror, the second facets 22 are also referred to as pupil facets.

The second facets 22 may likewise be macroscopic facets, which may for example have a round, rectangular or else hexagonal boundary, or may alternatively be facets composed of micromirrors. In this regard, reference is likewise made to DE 10 2008 009 600 A1.

The second facets 22 may have plane reflection surfaces or alternatively convexly or concavely curved reflection surfaces.

The illumination optical unit 4 consequently forms a doubly faceted system. This fundamental principle is also referred to as a fly's eye condenser (fly's eye integrator).

It can be advantageous to arrange the second facet mirror 21 not exactly in a plane that is optically conjugate to a pupil plane of the projection optical unit 10. In particular, the pupil facet mirror 22 can be arranged so as to be tilted relative to a pupil plane of the projection optical unit 10, as is described, for example, in DE 10 2017 220 586 A1.

The individual first facets 20 are imaged into the object field 5 with the aid of the second facet mirror 21 and optionally with the aid of an imaging optical assembly in the form of a transfer optical unit, which is not depicted in FIG. 1.

The transfer optical unit may comprise exactly one mirror, but alternatively also comprise two or more mirrors, which are arranged one behind the other in the beam path of the illumination optical unit 4. The transfer optical unit may in particular comprise one or two normal-incidence mirrors (NI mirrors) and/or one or two grazing-incidence mirrors (GI mirrors). The illumination optical unit 4 has exactly three mirrors in the embodiment shown in FIG. 1, that is to say downstream of the collector 17, specifically the deflection mirror US, the first facet mirror 19, and the second facet mirror 21.

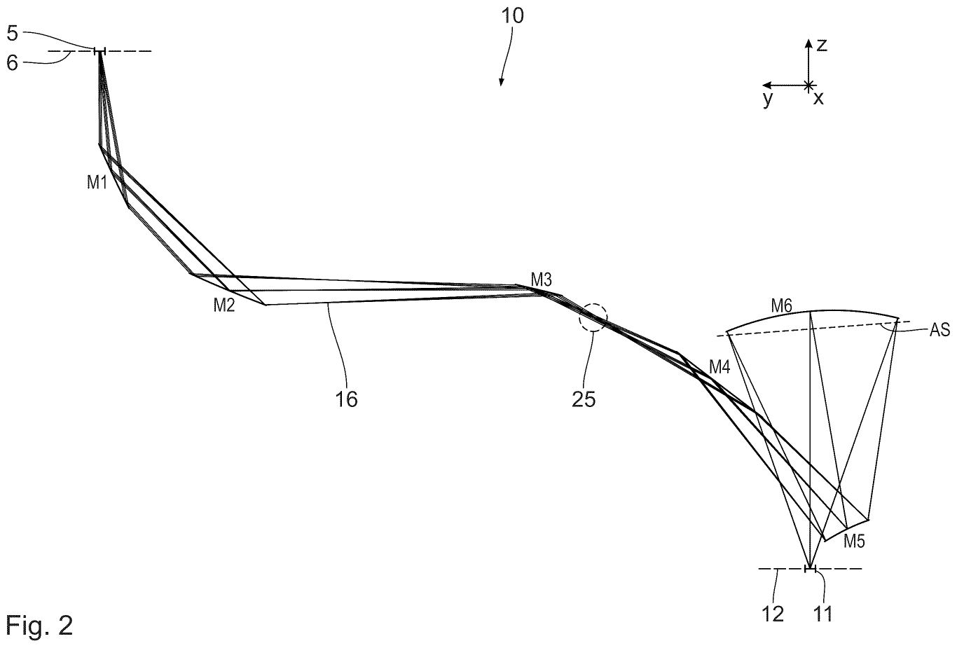

To the extent that the transfer optical unit downstream of the second facet mirror 21 is dispensed with, the second facet mirror 21 is the last beam shaping mirror or else indeed the last mirror for the illumination radiation 16 in the beam path upstream of the object field 5. An example of an illumination optical unit 4 without a transfer optical unit is disclosed in FIG. 2 of WO 2019/096654 A1.

The imaging of the first facets 20 into the object plane 6 via the second facets 22 or using the second facets 22 and a transfer optical unit is often only approximate imaging.

The projection optical unit 10 comprises a plurality of mirrors, namely six mirrors M1 to M6 (cf. FIG. 2), which are consecutively numbered in accordance with their order in the beam path of the projection exposure apparatus 1.

In the example illustrated in FIG. 1, the projection optical unit 10 comprises six mirrors M1 to M6. Alternatives with four, five or any other number of mirrors Mi are likewise possible.

The projection optical unit 10 is a non-obscured optical unit. None of the mirrors M1 to M6 includes a passage opening for the illumination radiation 16.

The projection optical unit 10 has an image-side numerical aperture of 0.33. Depending on the embodiment of the projection optical unit 10, the image-side numerical aperture may range between 0.25 and 0.4, for example. Depending on the embodiment, the image-side numerical aperture of the projection optical unit 10 may also adopt different values.

Reflection surfaces of the mirrors Mi are embodied as free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, for example with alternating layers of molybdenum and silicon. A ruthenium coating is also possible, in particular for coating mirrors for grazing incidence (GI mirrors).

The projection optical unit 10 leads to a reduction in size with a ratio of 4:1 in the x-direction, that is to say in a direction perpendicular to the scanning direction y. Moreover, the projection optical unit 10 leads to an image inversion in this x-direction. Thus, an imaging scale βₓ in the x-direction is-4.00.

In the scanning direction y, the projection optical unit 10 once again leads to a reduction in size of 4:1, but without an image inversion in this case (β_{y}=+4.00).

The projection optical unit 10 may also have an anamorphic design in an alternative embodiment. In that case, it has different imaging scales βₓ, β_{y} in the x- and y-directions. The two imaging scales βₓ, β_{y} of the projection optical unit 7 can be (βₓ, β_{y})=(+/−4, +/−8).

Other imaging scales are likewise possible. Imaging scales with the same sign are also possible in the x- and y-directions.

The image field 11 has an x-extent of 26 mm and a y-extent of 2.5 mm.

The image field may have a partial-ring-shaped embodiment.

Alternatively, the image field may also have a rectangular embodiment.

The number of intermediate image planes in the x-direction and in the y-direction in the beam path between the object field 5 and the image field 11 differ in the case of the projection optical unit 10. In the yz-plane, the projection optical unit 10 has an intermediate image in an intermediate image plane 24 between the mirrors M3 and M4, as shown in the meridional section according to FIG. 2. In the imaging direction perpendicular thereto with the imaging scale βₓ=−4.00, the projection optical unit 10 has no intermediate image. Examples of projection optical units with different numbers of such intermediate images in the x- and y-directions are known from US 2018/0074303 A1. Alternatively, the projection optical unit 10 may also be designed without an intermediate image or with the same number of intermediate images in the x- and y-directions.

In each case one of the pupil facets 22 is assigned to exactly one of the field facets 20 for forming in each case an illumination channel for illuminating the object field 5. In particular, this can yield illumination according to the Köhler principle. The far field is decomposed into a multiplicity of object fields 5 with the aid of the field facets 20. The field facets 20 produce a plurality of images of the intermediate focus on the pupil facets 22 respectively assigned thereto.

The field facets 20 are imaged, in each case by way of an assigned pupil facet 22, onto the reticle 7 in a manner such that they are superposed on one another for the purposes of illuminating the object field 5. The illumination of the object field 5 is in particular as homogeneous as possible. It can have a uniformity error of less than 2%. The field uniformity can be achieved by overlaying different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, in particular the subset of the pupil facets which guide light. This intensity distribution is also referred to as illumination setting or illumination pupil filling.

A likewise preferred pupil uniformity in the region of sections of an illumination pupil of the illumination optical unit 4 which are illuminated in a defined manner may be achieved by a redistribution of the illumination channels.

Further aspects and details of the illumination of the object field 5 and in particular of the entrance pupil of the projection optical unit 10 are described below.

The projection optical unit 10 may have in particular a homocentric entrance pupil. It may be accessible, like in the embodiment of the projection optical unit 10 according to FIG. 2.

The projection optical unit 10 has an entrance pupil EP (cf. FIG. 1) which both in the x-direction and in the y-direction is located in the range between 1500 mm and 2000 mm upstream of the object field 5 in the beam path, and is in particular located in the range between 1800 mm and 2200 mm. An arrangement plane of this entrance pupil is depicted at EP in FIG. 1. Thus, if the pupil facet mirror 21 is arranged approximately 2 m upstream of the object field 5 in the beam path of the illumination or imaging light 16, then the pupil facet mirror 21 satisfies the positional condition of “arrangement in the region of the entrance pupil of the projection optical unit”.

The entrance pupil may also be inaccessible in the case of an alternative embodiment of the projection optical unit 10, with the result that an arrangement plane of the pupil facet mirror 21 is imaged into the entrance pupil with the aid of further components of the illumination optical unit 4.

The entrance pupil of the projection optical unit 10 cannot, as a rule, be exactly illuminated using the pupil facet mirror 21. The aperture rays often do not intersect at a single point when imaging the projection optical unit 10 which telecentrically images the centre of the pupil facet mirror 21 onto the wafer 13. However, it is possible to find an area in which the spacing of the aperture rays that is determined in pairs becomes minimal. This area represents the entrance pupil or an area in real space that is conjugate thereto. In particular, this area has a finite curvature.

It may be the case that the projection optical unit 10 has different poses of the entrance pupil for the tangential beam path and for the sagittal beam path. In this case, an imaging element, in particular an optical component part of the transfer optical unit, should be provided between the second facet mirror 21 and the reticle 7. With the aid of this optical element, the different position of the tangential entrance pupil and the sagittal entrance pupil can be taken into account.

In the arrangement of the components of the illumination optical unit 4 illustrated in FIG. 1, the pupil facet mirror 21 is arranged so as to be tilted with respect to the object plane 5. The second facet mirror 21 is furthermore arranged so as to be tilted with respect to an arrangement plane defined by the first facet mirror 19.

Further details relating to the projection optical unit 10 are described hereinafter on the basis of FIG. 2.

The projection optical unit 10 has two NI mirrors (mirrors for normal incidence; normal incidence mirrors), namely the two last mirrors M5 and M6 in the imaging beam path of the projection optical unit 10. The imaging light 16 impinges on these two NI mirrors M5, M6 at angles of incidence of less than 45°. The maximum angle of incidence of the imaging light 16 incident on the respective NI mirror, may be less than 40°, may be less than 35°, may be less than 30°, may be less than 25°, may be less than 20°, may be less than 15° and may also be less than 10°.

The other mirrors M1 to M4 of the projection optical unit 10 are GI mirrors (mirrors for grazing incidence, grazing incidence mirrors). For these mirrors M1 to M4, there are angles of incidence of the illumination light 16 on the mirrors greater than 45° in each case. The minimum angle of incidence, which is incident on the respective GI mirror, may be greater than 50°, may be greater than 55°, may be greater than 60°, may be greater than 65°, may be greater than 70°, may be greater than 75° and may also be greater than 80°.

Information concerning reflection at a GI mirror (grazing incidence mirror) can be found in WO 2012/126867 A. Further information concerning the reflectivity of NI mirrors (normal incidence mirrors) can be found in DE 101 55 711 A.

None of the mirrors M1 to M6 has a passage opening and the mirrors are used in a reflective manner in a continuous region without gaps in each case.

FIG. 2 illustrates the calculated reflection surfaces of the mirrors M1 to M6. The used reflection surfaces of the mirrors M1 to M6 are carried in a known manner by mirror bodies (not shown).

An overall transmission of the projection optical unit 10, which emerges as a product of the reflectivities of the mirrors M1 to M6 for the illumination light 16 along the imaging beam path through the projection optical unit 10, has a value of 15.12% in the projection optical unit 10 according to FIG. 2. On average, each individual one of the mirrors M1 to M6 thus has a reflectivity of 73%.

The first two mirrors M1, M2 in the imaging beam path of the projection optical unit 10 are a pair of successive GI mirrors, which add in terms of their deflective effect. Accordingly, the two subsequent mirrors M3 and M4 in the imaging beam path of the projection optical unit 10 are a pair of successive GI mirrors, which add in terms of their deflective effect. These two pairs M1, M2 on the one hand and M3, M4 on the other hand, have deflective effects which are in the opposite sense to one another. That is to say, the deflective effect of the second GI mirror pair M3, M4 has a subtractive effect in relation to the deflective effect of the first GI mirror pair M1, M2.

In the yz-plane, a first pupil plane of the projection optical unit 10 is located in the beam path of the imaging light between the mirrors M2 and M3. A second pupil plane in the yz-plane is located at the same location as the pupil plane in the xz-plane perpendicular thereto, at a location in the imaging beam path adjacent to the reflection of the imaging light 16 at the mirror M6. An aperture can be limited in the case of the projection optical unit 10 by way of an aperture stop, which bounds the imaging beam path on the edge side, in particular, and which may be attached to the mirror M6. If desired, an inner obscuration may also be defined on the mirror M6 with the aid of an appropriate stop portion.

A y-offset between a central field point of the object field 5 and a central field point of the image field 11 is approximately 3570 mm in the case of the projection optical unit 10.

A z-distance between the mirror M5 and the image field 11 is 140 mm.

The distance between the object field 5 and the image field 11 is 2600 mm in the direction perpendicular to the object field.

The object plane 6 and the image plane 12 extend parallel to one another.

The entire projection optical unit 10 can be accommodated in a cuboid with the xyz-edge lengths of 860 mm, 4011 mm and 1993 mm.

The imaging beam path of the projection optical unit 10 contains a crossing region 25, in which two imaging beam path sections of the imaging beam path cross. A first of these crossing imaging beam path sections is the one between the mirrors M4 and M5. A second of these crossing imaging beam path sections is the section between the mirror M6 and the image field 11.

The mirrors M1 to M6 carry a coating that optimizes the reflectivity of the mirrors M1 to M6 for the imaging light 16. For the GI mirrors in particular, this may be a lanthanum coating, a boron coating or a boron coating with an uppermost layer of lanthanum, or else a ruthenium coating. Other coating materials may also be used, in particular lanthanum nitride and/or B₄C. In the mirrors M1 to M4 for grazing incidence, use can be made of a coating with one ply of boron or lanthanum, for example. The highly reflective layers, in particular of the mirrors M5 and M6 for normal incidence, can be configured as multi-ply layers, wherein successive layers can be manufactured from different materials. Alternating material layers can also be used. A typical multi-ply layer can have fifty bilayers, respectively made of a layer of boron and a layer of lanthanum. Layers containing lanthanum nitride and/or boron, in particular B₄C, may also be used.

Table 1, below, summarizes parameters of the projection optical unit 10. In addition to the data already explained above, Table 1 also specifies values for an angle of a chief ray of a central field point with respect to the z-axis (5.20)° and a usable étendue of the projection optical unit and a mean wavefront aberration RS.

TABLE 1 for FIG. 2

| Wavelength | 13.5 | nm |
|---|---|---|
| Image-side aperture | 0.33 | |
| βₓ | −4.00 (without | |
| | intermediate image) | |
| β_{y} | +4.00 (with | |
| | intermediate image) | |
| Chief ray angle | 5.20° | |
| Étendue | 7.08 | mm² |
| Mean wavefront aberration RMS | +175.579 | mλ |
| Overall transmission | 15.12% | |
| Position of the entrance pupil (x) | −2219.985 | mm |
| Position of the entrance pupil (y) | −2023.237 | mm |
| Object−image offset in the y-direction | 3567.91 | mm |
| Image field size (x) | 26 | mm |
| Image field size (y) | 2.5 | mm |
| Distance between M5 and image plane | 140 | mm |
| Distance between the object plane and | 2600.10 | mm |
| image plane | | |
| Tilt between the object and | 0.0° | |
| image plane | | |

| | |
|---|---|
| Installation space cuboid | (860 × 4011 × 1993) mm |

Tables 2a, 2b below summarize the parameters “maximum angle of incidence”, “extent of the reflection surface in the x-direction”, “extent of the reflection surface in the y-direction” and “maximum mirror diameter” for the mirrors M1 to M6 of the projection optical unit 10.

TABLE 2a for FIG. 2

| | M1 | M2 | M3 |
|---|---|---|---|
| Maximum angle of incidence [°] | 73.6 | 67.9 | 79.3 |
| Minimum angle of incidence [°] | 67.0 | 66.6 | 73.5 |
| Extent of the reflection surface | 240.6 | 347.5 | 552.9 |
| in the x-direction [mm] | | | |
| Extent of the reflection surface | 350.4 | 415.8 | 244.8 |
| in the y-direction [mm] | | | |
| Maximum mirror diameter [mm] | 374.1 | 440.6 | 557.3 |

TABLE 2b for FIG. 2

| | M4 | M5 | M6 |
|---|---|---|---|
| Maximum angle of incidence [°] | 83.5 | 27.3 | 5.6 |
| Minimum angle of incidence [°] | 75.6 | 6.3 | 2.9 |
| Extent of the reflection surface | 485.8 | 291.5 | 859.9 |
| in the x-direction [mm] | | | |
| Extent of the reflection surface | 535.8 | 237.7 | 859.9 |
| in the y-direction [mm] | | | |
| Maximum mirror diameter [mm] | 549.1 | 291.6 | 860.8 |

For the four GI mirrors M1 to M4, there is a minimum angle of incidence of the imaging light 16 of 66.6° and a maximum angle of incidence of 83.5°. For the two NI mirrors M5, M6, there is a minimum angle of incidence of 2.9° and a maximum angle of incidence of 27.3°. The maximum angle of incidence is less than 10° and in particular less than 6° at the last mirror M6.

The minimum angle of incidence is greater than 70° and is even greater than 73° at the last two GI mirrors M3, M4. The minimum angle of incidence is greater than 75° at the last GI mirror M4.

The mirror with the smallest reflection surface extent in the x-direction is the mirror M1, whose extent is less than 250 mm. The mirror with the smallest reflection surface extent in the y-direction is the mirror M5, with an extent of less than 240 mm. The y-extent of the mirrors M3 and M5 is less than 250 mm. All mirrors M1 to M6 have an x/y-reflection surface extent of more than 200 mm.

The largest mirror is the mirror M6, which is practically circular with a diameter of 860 mm.

The mirrors M1 to M6 are embodied as free-form surfaces which cannot be described by a rotationally symmetric function. Other embodiments of the projection optical unit 10, in which at least one of the mirrors M1 to M6 is embodied as a rotationally symmetric asphere, are also possible. It is also possible for all mirrors M1 to M6 to be embodied as such aspheres.

A free-form surface can be described by the following free-form surface equation (Equation 1):

$$Z = \frac{{c}_{x} {x}^{2} + {c}_{y} {y}^{2}}{1 + \sqrt{1 - ( 1 + {k}_{x} ) {( {c}_{x} x )}^{2} - ( 1 + {k}_{y} ) {( {c}_{y} y )}^{2}}} + {C}_{1} x + {C}_{2} y + {C}_{3} {x}^{2} + {C}_{4} xy + {C}_{5} {y}^{2} + {C}_{6} {x}^{3} + … + {C}_{9} {y}^{3} + {C}_{10} {x}^{4} + … + {C}_{12} {x}^{2} {y}^{2} + … + {C}_{14} {y}^{4} + {C}_{15} {x}^{5} + … + {C}_{20} {y}^{5} + {C}_{21} {x}^{6} + … + {C}_{24} {x}^{3} {y}^{3} + … + {C}_{27} {y}^{6} + … \qquad ( 1 )$$

The following applies to the parameters of this Equation (1):

Z is the sagittal height of the free-form surface at the point x, y, where x²+y²=r². Here, r is the distance from the reference axis of the free-form surface equation (x=0; y=0).

In the free-form surface Equation (1), C₁, C₂, C₃ . . . denote the coefficients of the free-form surface series expansion in powers of x and y.

In the case of a conical base area, cₓ, c_{y} is a constant corresponding to the vertex curvature of a corresponding asphere. Thus, cₓ=1/Rₓ (1/RDX) and c_{y}=1/R_{y} (1/RDY) applies. kₓ and k_{y} (CCX, CCY) each correspond to a conic constant of a corresponding asphere. Thus, Equation (1) describes a biconical free-form surface.

An alternative possible free-form surface can be produced from a rotationally symmetric reference surface. Such free-form surfaces for reflection surfaces of the mirrors of projection optical units of microlithographic projection exposure apparatuses are known from US 2007 0 058 269 A1.

Alternatively, free-form surfaces can also be described with the aid of two-dimensional spline surfaces. Examples for this are Bezier curves or non-uniform rational basis splines (NURBS). By way of example, two-dimensional spline surfaces can be described by a grid of points in an xy-plane and associated z-values, or by these points and gradients associated therewith. Depending on the respective type of the spline surface, the complete surface is obtained by interpolation between the grid points using for example polynomials or functions which have specific properties in respect of the continuity and differentiability thereof. Examples for this are analytical functions.

The optical design data of the reflection surfaces of the mirrors M1 to M6 of the projection optical unit 10 can be gathered from the further tables below.

Table 3 specifies coordinates of a surface origin of a respective mirror surface and of an area of the object field 5, in relation to a xyz-coordinate system of the image field 11.

The first column specifies the distance of the respective mirror or of the object field 5 from a coordinate origin in the centre of the image field 11 in the y-direction (first column) and in the z-direction (second column).

The additional columns of Table 3 additionally specify tilt values of the respective surface of the mirror M1 to M6 or of the object field 5 in relation to the x-, y- and z-axis. In the embodiment according to FIG. 2, neither the object field 5 nor the image field 11 are tilted with respect to the x-axis and extend parallel to one another.

Table 4 tabulates, separately for the mirrors M1 to M6, the parameters RDX, RDY, CCX, CCY and, sorted according to the powers in x and y, the values of the coefficients C1, C2, C3 . . . of the free-form surface series expansion according to Equation (1) above.

Table 5 tabulates the reflectivities of the mirrors M1 to M6 and also the total or overall transmission of the projection optical unit 10, which is 15.4584%.

Table 6 tabulates opening data for an aperture stop AS of the projection optical unit 10 arranged in the region of the mirror M6. This aperture opening is defined by a polygon, the x- and y-values of which are specified in Table 6.

Mirrors with different signs for the values RDX and RDY have a saddle point-type or minimax basic shape.

TABLE 3a for FIG. 2

| | y-distance | z-distance | Tilt about the x-axis |
|---|---|---|---|
| | [mm] | [mm] | [degrees] |
| Object field | 3567.908119 | 2600.104852 | −0.000000 |
| M1 | 3513.528571 | 2002.574213 | 65.101421 |
| M2 | 2915.894055 | 1396.476224 | 202.479826 |
| M3 | 1393.145977 | 1408.255078 | 13.144114 |
| M4 | 495.301563 | 956.069380 | 37.339438 |
| M5 | −186.764134 | 199.954174 | −25.871920 |
| M6 | 0.000000 | 1293.569087 | −4.845651 |
| Stop (AS) | −186.764134 | 199.954174 | −9.691301 |
| Image field | 0.000000 | 0.000000 | −0.000000 |

TABLE 3b for FIG. 2

| | y-distance | Tilt about the y- | Tilt about the z-axis |
|---|---|---|---|
| | [mm] | axis [degrees] | [degrees] |
| Object field | 3567.908119 | 0.00 | −0.00 |
| M1 | 3513.528571 | 180.00 | 0.00 |
| M2 | 2915.894055 | 0.00 | −0.00 |
| M3 | 1393.145977 | 0.00 | 180.00 |
| M4 | 495.301563 | 0.00 | −0.00 |
| M5 | −186.764134 | 180.00 | 0.00 |
| M6 | 0.000000 | 0.00 | −0.00 |
| Stop (AS) | −186.764134 | 180.00 | 0.00 |
| Image field | 0.000000 | 0.00 | −0.00 |

TABLE 4 for FIG. 2

| | |
|---|---|
| M1 | |
| RDX | −1760.946185 |
| RDY | −5237.759532 |
| CCX | 0.000000 |
| CCY | 0.000000 |
| x**i * y**j | Coefficient |
| x**2 * y**1 | 6.406136e−08 |
| x**0 * y**3 | −6.433069e−08 |
| x**4 * y**0 | 1.000447e−11 |
| x**2 * y**2 | −4.764589e−11 |
| x**0 * y**4 | 4.633559e−11 |
| x**4 * y**1 | −1.829146e−14 |
| x**2 * y**3 | 2.455213e−14 |
| x**0 * y**5 | −1.054203e−13 |
| x**6 * y**0 | 1.746749e−16 |
| x**4 * y**2 | 1.495781e−16 |
| x**2 * y**4 | −2.484178e−16 |
| x**0 * y**6 | 8.721206e−17 |
| x**6 * y**1 | −3.515794e−18 |
| x**4 * y**3 | −1.498001e−18 |
| x**2 * y**5 | 4.457463e−19 |
| x**0 * y**7 | 2.677524e−19 |
| x**8 * y**0 | −3.664711e−20 |
| x**6 * y**2 | −3.106743e−20 |
| x**4 * y**4 | −7.085191e−21 |
| x**2 * y**6 | 1.683354e−21 |
| x**0 * y**8 | −2.551276e−22 |
| x**8 * y**1 | 1.729245e−22 |
| x**6 * y**3 | 3.050984e−22 |
| x**4 * y**5 | 1.862203e−23 |
| x**2 * y**7 | 1.735637e−23 |
| x**0 * y**9 | −5.208052e−24 |
| x**10 * y**0 | 2.330707e−24 |
| x**8 * y**2 | 2.843855e−24 |
| x**6 * y**4 | 1.798415e−24 |
| x**4 * y**6 | −2.599972e−25 |
| x**2 * y**8 | 5.134572e−26 |
| x**0 * y**10 | −1.400791e−26 |
| x**10 * y**1 | −2.573046e−27 |
| x**8 * y**3 | −6.423368e−27 |
| x**6 * y**5 | −4.901082e−27 |
| x**4 * y**7 | −2.458385e−29 |
| x**2 * y**9 | −2.747342e−28 |
| x**0 * y**11 | −2.005664e−28 |
| x**12 * y**0 | −5.202450e−29 |
| x**10 * y**2 | −6.867124e−29 |
| x**8 * y**4 | −6.100441e−29 |
| x**6 * y**6 | −1.995147e−29 |
| x**4 * y**8 | 6.903854e−30 |
| x**2 * y**10 | −1.581698e−30 |
| x**0 * y**12 | −6.100383e−31 |
| M2 | |
| RDX | 17482.656386 |
| RDY | −6010.436574 |
| CCX | 0.000000 |
| CCY | 0.000000 |
| x**i * y**j | Coefficient |
| x**2 * y**1 | 1.399225e−07 |
| x**0 * y**3 | 2.105416e−08 |
| x**4 * y**0 | −1.126305e−10 |
| x**2 * y**2 | 3.499238e−11 |
| x**0 * y**4 | −8.683992e−12 |
| x**4 * y**1 | −1.372085e−13 |
| x**2 * y**3 | −5.010190e−14 |
| x**0 * y**5 | 1.318466e−13 |
| x**6 * y**0 | 7.252188e−17 |
| x**4 * y**2 | 7.955072e−17 |
| x**2 * y**4 | −5.820814e−16 |
| x**0 * y**6 | 1.782464e−16 |
| x**6 * y**1 | 1.205256e−19 |
| x**4 * y**3 | 1.204799e−18 |
| x**2 * y**5 | −2.236854e−18 |
| x**0 * y**7 | −1.131829e−18 |
| x**8 * y**0 | 2.441587e−21 |
| x**6 * y**2 | 2.072854e−21 |
| x**4 * y**4 | 1.052274e−20 |
| x**2 * y**6 | 1.261384e−20 |
| x**0 * y**8 | −9.254009e−21 |
| x**8 * y**1 | 8.492242e−25 |
| x**6 * y**3 | −3.822826e−23 |
| x**4 * y**5 | −5.684027e−23 |
| x**2 * y**7 | 1.028469e−22 |
| x**0 * y**9 | 2.643501e−24 |
| x**10 * y**0 | −5.556497e−26 |
| x**8 * y**2 | −8.556832e−26 |
| x**6 * y**4 | 1.022405e−25 |
| x**4 * y**6 | −4.403374e−25 |
| x**2 * y**8 | −5.810470e−26 |
| x**0 * y**10 | 4.403417e−26 |
| x**10 * y**1 | −2.448642e−29 |
| x**8 * y**3 | 1.075413e−28 |
| x**6 * y**5 | 1.510835e−27 |
| x**4 * y**7 | 9.447116e−29 |
| x**2 * y**9 | −5.592951e−28 |
| x**0 * y**11 | −2.079429e−29 |
| x**12 * y**0 | 3.638082e−31 |
| x**10 * y**2 | 1.497973e−30 |
| x**8 * y**4 | −2.383690e−30 |
| x**6 * y**6 | −1.990041e−30 |
| x**4 * y**8 | 1.862157e−30 |
| x**2 * y**10 | 6.728020e−31 |
| x**0 * y**12 | −4.844624e−32 |
| M3 | |
| RDX | −1252.860823 |
| RDY | −6353.177499 |
| CCX | 0.000000 |
| CCY | 0.000000 |
| x**i * y**j | Coefficient |
| x**2 * y**1 | 5.763516e−09 |
| x**0 * y**3 | −1.103481e−08 |
| x**4 * y**0 | 1.229126e−11 |
| x**2 * y**2 | 8.768648e−12 |
| x**0 * y**4 | −3.900753e−12 |
| x**4 * y**1 | −2.042166e−14 |
| x**2 * y**3 | 2.113252e−14 |
| x**0 * y**5 | 1.388383e−13 |
| x**6 * y**0 | 1.927140e−17 |
| x**4 * y**2 | 2.415560e−17 |
| x**2 * y**4 | 8.655066e−17 |
| x**0 * y**6 | 2.283663e−17 |
| x**6 * y**1 | −6.232552e−20 |
| x**4 * y**3 | −2.248586e−19 |
| x**2 * y**5 | −2.028411e−18 |
| x**0 * y**7 | −2.035040e−17 |
| x**8 * y**0 | −9.637963e−23 |
| x**6 * y**2 | −4.672737e−22 |
| x**4 * y**4 | −2.280757e−21 |
| x**2 * y**6 | −1.407526e−20 |
| x**0 * y**8 | 6.975746e−20 |
| x**8 * y**1 | 3.793096e−25 |
| x**6 * y**3 | −8.300586e−25 |
| x**4 * y**5 | 1.970293e−23 |
| x**2 * y**7 | 2.546581e−22 |
| x**0 * y**9 | 1.311848e−21 |
| x**10 * y**0 | 1.202878e−28 |
| x**8 * y**2 | 3.453621e−28 |
| x**6 * y**4 | 4.824982e−26 |
| x**4 * y**6 | −1.648306e−25 |
| x**2 * y**8 | 1.249094e−24 |
| x**0 * y**10 | −9.498957e−24 |
| x**10 * y**1 | −6.313414e−31 |
| x**8 * y**3 | 4.925126e−29 |
| x**6 * y**5 | −3.284459e−28 |
| x**4 * y**7 | 2.110322e−27 |
| x**2 * y**9 | −2.598280e−26 |
| x**0 * y**11 | 6.879295e−27 |
| x**12 * y**0 | 2.155258e−33 |
| x**10 * y**2 | 4.321712e−32 |
| x**8 * y**4 | −1.405714e−31 |
| x**6 * y**6 | 1.343962e−30 |
| x**4 * y**8 | −9.192435e−30 |
| x**2 * y**10 | 8.624423e−29 |
| x**0 * y**12 | 5.351773e−29 |
| M4 | |
| RDX | −1441.900784 |
| RDY | 59943.749225 |
| CCX | 0.000000 |
| CCY | 0.000000 |
| x**i * y**j | Coefficient |
| x**2 * y**1 | 1.549588e−07 |
| x**0 * y**3 | 2.950403e−08 |
| x**4 * y**0 | −2.019838e−11 |
| x**2 * y**2 | −5.954269e−11 |
| x**0 * y**4 | 4.141965e−11 |
| x**4 * y**1 | 1.413198e−13 |
| x**2 * y**3 | 8.225660e−14 |
| x**0 * y**5 | 3.998081e−14 |
| x**6 * y**0 | 1.100566e−17 |
| x**4 * y**2 | −1.283482e−16 |
| x**2 * y**4 | 4.984228e−17 |
| x**0 * y**6 | −1.734188e−18 |
| x**6 * y**1 | −2.486322e−21 |
| x**4 * y**3 | 2.517291e−19 |
| x**2 * y**5 | −1.831486e−19 |
| x**0 * y**7 | −3.403598e−19 |
| x**8 * y**0 | −3.431398e−23 |
| x**6 * y**2 | −1.030752e−21 |
| x**4 * y**4 | −2.369550e−21 |
| x**2 * y**6 | −2.902918e−21 |
| x**0 * y**8 | −1.239722e−21 |
| x**8 * y**1 | 2.954455e−25 |
| x**6 * y**3 | 1.741106e−25 |
| x**4 * y**5 | −7.711712e−24 |
| x**2 * y**7 | −7.817498e−24 |
| x**0 * y**9 | 2.707831e−25 |
| x**10 * y**0 | 4.265635e−27 |
| x**8 * y**2 | 1.962032e−26 |
| x**6 * y**4 | 1.773890e−26 |
| x**4 * y**6 | 5.434733e−27 |
| x**2 * y**8 | 1.640253e−26 |
| x**0 * y**10 | 1.295684e−26 |
| x**10 * y**1 | −1.116084e−30 |
| x**8 * y**3 | −2.019029e−29 |
| x**6 * y**5 | 2.678016e−29 |
| x**4 * y**7 | 1.402944e−28 |
| x**2 * y**9 | 1.244088e−28 |
| x**0 * y**11 | 3.447209e−29 |
| x**12* y**0 | −3.070120e−32 |
| x**10 * y**2 | −1.176180e−31 |
| x**8 * y**4 | −1.083643e−31 |
| x**6 * y**6 | 1.476958e−31 |
| x**4 * y**8 | 3.233136e−31 |
| x**2 * y**10 | 1.739797e−31 |
| x**0 * y**12 | 3.058760e−32 |
| M5 | |
| RDX | 814.915668 |
| RDY | 1064.785763 |
| CCX | 0.000000 |
| CCY | 0.000000 |
| x**i * y**j | Coefficient |
| x**2 * y**1 | −2.523860e−07 |
| x**0 * y**3 | −3.711242e−07 |
| x**4 * y**0 | 6.424692e−10 |
| x**2 * y**2 | 1.577065e−09 |
| x**0 * y**4 | 2.691353e−10 |
| x**4 * y**1 | −1.412585e−12 |
| x**2 * y**3 | −2.101526e−12 |
| x**0 * y**5 | −8.424872e−13 |
| x**6 * y**0 | 2.658374e−15 |
| x**4 * y**2 | 9.128788e−15 |
| x**2 * y**4 | 4.343159e−15 |
| x**0 * y**6 | 1.003564e−15 |
| x**6 * y**1 | −6.699348e−18 |
| x**4 * y**3 | −1.049497e−17 |
| x**2 * y**5 | 1.530269e−18 |
| x**0 * y**7 | −2.675489e−17 |
| x**8 * y**0 | 1.123665e−20 |
| x**6 * y**2 | 4.721025e−20 |
| x**4 * y**4 | 1.976406e−20 |
| x**2 * y**6 | 3.561459e−20 |
| x**0 * y**8 | 2.021328e−19 |
| x**8 * y**1 | −1.393489e−22 |
| x**6 * y**3 | −6.655753e−22 |
| x**4 * y**5 | −1.119129e−21 |
| x**2 * y**7 | −2.216427e−21 |
| x**0 * y**9 | −2.263138e−22 |
| x**10 * y**0 | 1.069370e−25 |
| x**8 * y**2 | 1.818265e−24 |
| x**6 * y**4 | 5.415765e−24 |
| x**4 * y**6 | 1.059522e−23 |
| x**2 * y**8 | 1.364480e−23 |
| x**0 * y**10 | 5.019754e−24 |
| x**10 * y**1 | 1.104013e−27 |
| x**8 * y**3 | 1.111711e−26 |
| x**6 * y**5 | 2.263477e−26 |
| x**4 * y**7 | 1.337363e−27 |
| x**2 * y**9 | 1.610230e−26 |
| x**0 * y**11 | 9.938594e−29 |
| x**12 * y**0 | −7.805277e−31 |
| x**10 * y**2 | −3.812939e−29 |
| x**8 * y**4 | −1.718695e−28 |
| x**6 * y**6 | −2.528162e−28 |
| x**4 * y**8 | −2.133976e−28 |
| x**2 * y**10 | −2.264975e−28 |
| x**0 * y**12 | −1.753868e−28 |
| M6 | |
| RDX | −1437.718613 |
| RDY | −1393.710808 |
| CCX | 0.000000 |
| CCY | 0.000000 |
| x**i * y**j | Coefficient |
| x**2 * y**1 | 4.601597e−09 |
| x**0 * y**3 | 1.043431e−08 |
| x**4 * y**0 | −4.977031e−12 |
| x**2 * y**2 | −9.057223e−12 |
| x**0 * y**4 | −2.475770e−12 |
| x**4 * y**1 | 3.280234e−15 |
| x**2 * y**3 | 8.426880e−15 |
| x**0 * y**5 | 6.559054e−15 |
| x**6 * y**0 | −2.653887e−18 |
| x**4 * y**2 | −8.372822e−18 |
| x**2 * y**4 | −6.336595e−18 |
| x**0 * y**6 | −2.218949e−18 |
| x**6 * y**1 | 1.150051e−21 |
| x**4 * y**3 | 4.671247e−21 |
| x**2 * y**5 | 5.114692e−21 |
| x**0 * y**7 | 4.792744e−21 |
| x**8 * y**0 | −4.899836e−25 |
| x**6 * y**2 | 4.944263e−24 |
| x**4 * y**4 | 7.348172e−24 |
| x**2 * y**6 | 3.520540e−24 |
| x**0 * y**8 | 1.842609e−25 |
| x**8 * y**1 | 3.250363e−27 |
| x**6 * y**3 | 1.559184e−26 |
| x**4 * y**5 | 2.518773e−26 |
| x**2 * y**7 | 2.679849e−26 |
| x**0 * y**9 | 2.825601e−27 |
| x**10 * y**0 | −6.406000e−30 |
| x**8 * y**2 | −1.052891e−28 |
| x**6 * y**4 | −2.266009e−28 |
| x**4 * y**6 | −1.722895e−28 |
| x**2 * y**8 | −6.592506e−29 |
| x**0 * y**10 | −1.186383e−29 |
| x**10 * y**1 | −5.787120e−33 |
| x**8 * y**3 | −3.793665e−32 |
| x**6 * y**5 | −7.081706e−32 |
| x**4 * y**7 | −8.416613e−32 |
| x**2 * y**9 | −7.740717e−32 |
| x**0 * y**11 | −4.059046e−32 |
| x**12 * y**0 | 2.034921e−35 |
| x**10 * y**2 | 4.604484e−34 |
| x**8 * y**4 | 1.360790e−33 |
| x**6 * y**6 | 1.519608e−33 |
| x**4 * y**8 | 7.580739e−34 |
| x**2 * y**10 | 1.451376e−34 |
| x**0 * y**12 | −6.878871e−36 |
| x**12 * y**1 | 5.707160e−39 |
| x**10 * y**3 | 5.127100e−38 |
| x**8 * y**5 | 1.132638e−37 |
| x**6 * y**7 | 1.424641e−37 |
| x**4 * y**9 | 1.755082e−37 |
| x**2 * y**11 | 1.451319e−37 |
| x**0 * y**13 | 8.495699e−38 |
| x**14 * y**0 | −2.827501e−41 |
| x**12 * y**2 | −7.789406e−40 |
| x**10 * y**4 | −2.951970e−39 |
| x**8 * y**6 | −4.503472e−39 |
| x**6 * y**8 | −3.370191e−39 |
| x**4 * y**10 | −1.257640e−39 |
| x**2 * y**12 | −1.151027e−40 |
| x**0 * y**14 | 8.334981e−41 |

TABLE 5
for FIG. 2

| Mirrors | Reflectivity |
|---|---|
| M6 | 0.676098 |
| M5 | 0.651536 |
| M4 | 0.848054 |
| M3 | 0.801719 |
| M2 | 0.706179 |
| M1 | 0.730898 |
| Overall transmission | 0.154584 |

TABLE 6
for FIG. 2

| x [mm] | y [mm] |
|---|---|
| −0.000 | 127.595 |
| −27.002 | 125.095 |
| −52.977 | 117.734 |
| −76.939 | 105.912 |
| −97.975 | 90.258 |
| −115.276 | 71.569 |
| −128.175 | 50.731 |
| −136.163 | 28.644 |
| −138.918 | 6.190 |
| −136.321 | −15.796 |
| −128.465 | −36.532 |
| −115.654 | −55.303 |
| −98.384 | −71.471 |
| −77.319 | −84.515 |
| −53.268 | −94.064 |
| −27.159 | −99.882 |
| 0.000 | −101.835 |
| 27.159 | −99.882 |
| 53.268 | −94.064 |
| 77.319 | −84.515 |
| 98.384 | −71.471 |
| 115.654 | −55.303 |
| 128.465 | −36.532 |
| 136.321 | −15.796 |
| 138.918 | 6.190 |
| 136.163 | 28.644 |
| 128.175 | 50.731 |
| 115.276 | 71.569 |
| 97.975 | 90.258 |
| 76.939 | 105.912 |
| 52.977 | 117.734 |
| 27.002 | 125.095 |

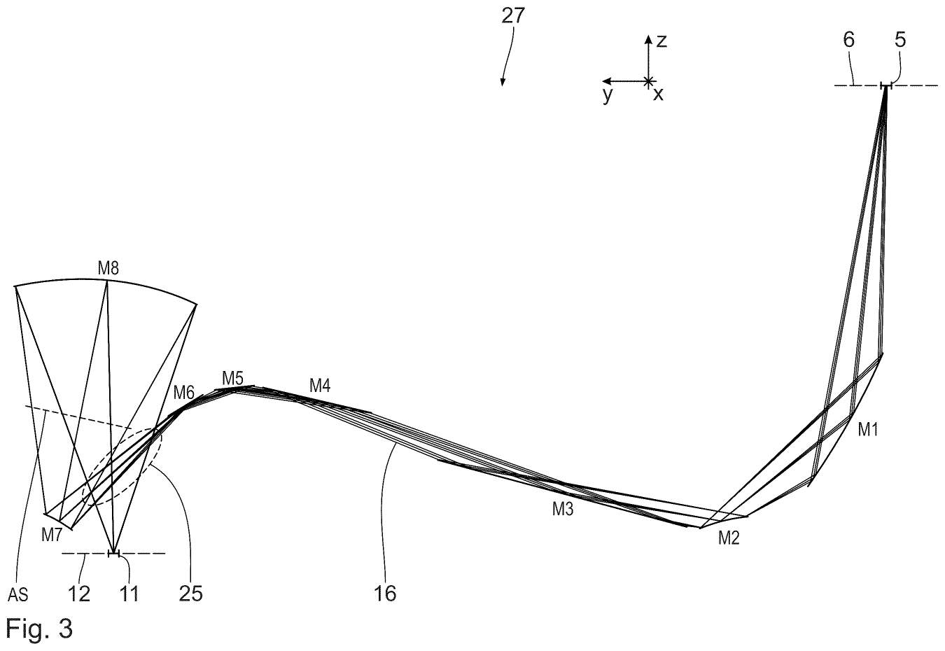

FIG. 3 shows a further embodiment of a projection optical unit or imaging optical unit 27, which can be used in the projection exposure apparatus 1 instead of the projection optical unit 10 of the embodiment according to FIG. 2. Components and functions corresponding to those which have already been explained above in conjunction with FIGS. 1 and 2, and in particular in conjunction with FIG. 2, are denoted by the same reference signs and are not discussed in detail again.

Starting from the object field 5, a beam path of the projection optical unit 27 initially runs over three GI mirrors M1, M2 and M3, which add in terms of their deflective effect, with the result that an overall deflection effect of slightly more than 90° arises for the imaging light 16. Over the further course of the beam path, the imaging light 16 is reflected at three further GI mirrors M4, M5 and M6, the deflective effect of which is counter to the deflective effects of the mirrors M1 to M3 and which in turn add in terms of their deflective effect. This overall deflection effect of the mirrors M4 to M6 is approximately 60°. Thus, the projection optical unit 27 has a total of six GI mirrors.

Subsequently, the imaging light 16 is reflected at an NI mirror M7 and, following this, it is reflected at the last NI mirror M8, which defines the image-side numerical aperture of the projection optical unit 27. None of the mirrors M1 to M8 includes a passage opening for the imaging light 16.

A pupil plane which can be used for an aperture stop AS is located in the beam path of the imaging light 16, between the mirrors M7 and M8.

Like in the case of the projection optical unit 10 as well, the penultimate mirror of the projection optical unit 27 is located in the beam path of the imaging light 16 (mirror M5 of the projection optical unit 10; mirror M7 of the projection optical unit 27), on the opposite side of a beam path section between the last aperture-limiting mirror (M6/M8) and the image field 11 in relation to the other mirrors of the projection optical units 10 and 27.

The following tables summarize parameters and the optical design of the projection optical unit 27. In terms of their structure, these tables correspond to those already explained above in conjunction with FIG. 2.

TABLE 1
for FIG. 3

| Wavelength | 13.5 | nm |
|---|---|---|
| Image-side aperture | 0.33 | |
| βₓ | −4.00 (without | |
| | intermediate image) | |
| β_{y} | 4.00 (with intermediate | |
| | image) | |
| Chief ray angle | 5.87° | |
| Étendue | 7.08 | mm² |
| Mean wavefront aberration RMS | 157.67 | mλ |
| Overall transmission | 11.90% | |
| Position of the entrance pupil (x) | −2164.72 | mm |
| Position of the entrance pupil (y) | −2131.42 | mm |
| Object-image offset in the y-direction | 3800.00 | mm |
| Image field size (x) | 26 | mm |
| Image field size (y) | 2.5 | mm |
| Distance between M7 and image plane | 124 | mm |
| Distance between the object plane and | 2301.15 | mm |

| | |
|---|---|
| image plane | |
| Tilt between the object and | 0.0° |
| Image plane | |
| Installation space cuboid | (911 × 4243 × 1227) mm |

TABLE 2a
for FIG. 3

| | M1 | M2 | M3 | M4 |
|---|---|---|---|---|
| Maximum angle of incidence [°] | 67.7 | 71.7 | 85.2 | 84.5 |
| Minimum angle of incidence [°] | 63.9 | 64.0 | 83.1 | 79.0 |
| Extent of the reflection surface | 462.9 | 544.9 | 527.8 | 463.6 |
| in the x-direction [mm] | | | | |
| Extent of the reflection surface | 736.6 | 224.3 | 1243.9 | 527.5 |
| in the y-direction [mm] | | | | |
| Maximum mirror diameter [mm] | 756.2 | 544.9 | 1249.5 | 608.0 |

TABLE 2b
for FIG. 3

| | M5 | M6 | M7 | M8 |
|---|---|---|---|---|
| Maximum angle of incidence [°] | 82.2 | 82.0 | 29.5 | 6.7 |
| Minimum angle of incidence [°] | 74.3 | 74.1 | 7.0 | 5.0 |
| Extent of the reflection surface | 458.4 | 450.2 | 313.4 | 910.7 |
| in the x-direction [mm] | | | | |
| Extent of the reflection surface | 172.2 | 186.1 | 148.6 | 894.8 |
| in the y-direction [mm] | | | | |
| Maximum mirror diameter [mm] | 463.5 | 451.8 | 313.4 | 911.3 |

TABLE 3a
for FIG. 3

| | | | Tilt about |
|---|---|---|---|
| | y-distance | z-distance | the x-axis |
| | [mm] | [mm] | [degrees] |
| Object field | 3800.003886 | 2301.154447 | −0.000000 |
| M1 | 3632.805120 | 675.181589 | 61.417114 |
| M2 | 2986.815842 | 157.548151 | 194.548927 |
| M3 | 2235.173063 | 284.779726 | −14.963247 |
| M4 | 853.247408 | 796.491442 | −12.383322 |
| M5 | 600.262003 | 816.169093 | 6.988275 |
| M6 | 370.147843 | 739.512505 | 30.480551 |
| M7 | −253.736945 | 167.087017 | −29.817950 |
| M8 | 0.000000 | 1343.366093 | −6.086420 |
| Stop (AS) | −146.582552 | 663.835608 | −12.172840 |
| Image field | 0.000000 | 0.000000 | −0.000000 |

TABLE 3b
for FIG. 3

| | | | Tilt about |
|---|---|---|---|
| | y-distance | Tilt about the | the z-axis |
| | [mm] | y-axis [degrees] | [degrees] |
| Object field | 3800.003886 | 0.00 | −0.00 |
| M1 | 3632.805120 | 180.00 | 0.00 |
| M2 | 2986.815842 | 0.00 | −0.00 |
| M3 | 2235.173063 | 180.00 | 0.00 |
| M4 | 853.247408 | −0.00 | −0.00 |
| M5 | 600.262003 | 0.00 | 180.00 |
| M6 | 370.147843 | 0.00 | −0.00 |
| M7 | −253.736945 | 180.00 | 0.00 |
| M8 | 0.000000 | 0.00 | −0.00 |
| Stop (AS) | −146.582552 | 180.00 | 0.00 |
| Image field | 0.000000 | 0.00 | −0.00 |

TABLE 4
FIG. 3

| | |
|---|---|
| M1 | |
| RDX | −3392.413258 |
| RDY | −3541.261916 |
| CCX | 0.000000 |
| CCY | 0.000000 |
| x**i * y**j | Coefficient |
| x**2 * y**1 | 7.669713e−09 |
| x**0 * y**3 | 3.461858e−08 |
| x**4 * y**0 | 1.703295e−11 |
| x**2 * y**2 | −7.017329e−12 |
| x**0 * y**4 | −3.239278e−11 |
| x**4 * y**1 | 8.812347e−15 |
| x**2 * y**3 | 1.170367e−14 |
| x**0 * y**5 | 2.387645e−14 |
| x**6 * y**0 | −6.795346e−18 |
| x**4 * y**2 | 9.575026e−18 |
| x**2 * y**4 | −1.356156e−17 |
| x**0 * y**6 | −6.540952e−17 |
| x**6 * y**1 | −2.458175e−21 |
| x**4 * y**3 | 5.092915e−21 |
| x**2 * y**5 | 8.095220e−20 |
| x**0 * y**7 | 1.147232e−19 |
| x**8 * y**0 | 8.396015e−23 |
| x**6 * y**2 | −3.601376e−23 |
| x**4 * y**4 | −1.016965e−22 |
| x**2 * y**6 | −1.126336e−22 |
| x**0 * y**8 | −7.512382e−24 |
| x**8 * y**1 | 4.931643e−27 |
| x**6 * y**3 | −1.322977e−25 |
| x**4 * y**5 | 1.158704e−25 |
| x**2 * y**7 | −1.180292e−25 |
| x**0 * y**9 | 4.948356e−26 |
| x**10 * y**0 | 5.405453e−29 |
| x**8 * y**2 | −5.071741e−28 |
| x**6 * y**4 | 2.217663e−29 |
| x**4 * y**6 | 5.252069e−28 |
| x**2 * y**8 | −2.118197e−29 |
| x**0 * y**10 | −8.637652e−29 |
| M2 | |
| RDX | −3292.080005 |
| RDY | 1481.984572 |
| CCX | 0.000000 |
| CCY | 0.000000 |
| x**i * y**j | Coefficient |
| x**2 * y**1 | −8.610316e−08 |
| x**0 * y**3 | −5.573778e−08 |
| x**4 * y**0 | −4.761204e−12 |
| x**2 * y**2 | 5.342179e−11 |
| x**0 * y**4 | 6.974044e−10 |
| x**4 * y**1 | 2.886130e−14 |
| x**2 * y**3 | −6.193769e−13 |
| x**0 * y**5 | −5.372573e−12 |
| x**6 * y**0 | 1.619272e−18 |
| x**4 * y**2 | 1.018999e−16 |
| x**2 * y**4 | 3.365180e−15 |
| x**0 * y**6 | 3.647141e−14 |
| x**6 * y**1 | −7.178651e−20 |
| x**4 * y**3 | −4.265293e−19 |
| x**2 * y**5 | −3.686009e−17 |
| x**0 * y**7 | 2.816087e−16 |
| x**8 * y**0 | −6.532861e−23 |
| x**6 * y**2 | −2.657085e−22 |
| x**4 * y**4 | 2.064932e−20 |
| x**2 * y**6 | −1.306626e−19 |
| x**0 * y**8 | 1.213070e−18 |
| x**8 * y**1 | 7.992184e−25 |
| x**6 * y**3 | −2.950675e−24 |
| x**4 * y**5 | 5.978120e−23 |
| x**2 * y**7 | −6.328843e−22 |
| x**0 * y**9 | 5.741619e−21 |
| x**10 * y**0 | 1.578306e−28 |
| x**8 * y**2 | 5.580327e−27 |
| x**6 * y**4 | −2.519659e−26 |
| x**4 * y**6 | −3.148591e−25 |
| x**2 * y**8 | −6.197273e−24 |
| x**0 * y**10 | 6.195741e−26 |
| M3 | |
| RDX | −5633.911904 |
| RDY | −21861.916811 |
| CCX | 0.000000 |
| CCY | 0.000000 |
| x**i * y**j | Coefficient |
| x**2 * y**1 | 2.946316e−08 |
| x**0 * y**3 | −2.336458e−09 |
| x**4 * y**0 | −7.906282e−11 |
| x**2 * y**2 | −1.528884e−11 |
| x**0 * y**4 | −3.301249e−12 |
| x**4 * y**1 | 5.864822e−14 |
| x**2 * y**3 | 8.162620e−15 |
| x**0 * y**5 | −8.615315e−16 |
| x**6 * y**0 | −1.940344e−17 |
| x**4 * y**2 | −2.006574e−17 |
| x**2 * y**4 | −8.026618e−19 |
| x**0 * y**6 | −3.823107e−19 |
| x**6 * y**1 | 5.838093e−20 |
| x**4 * y**3 | 6.378118e−21 |
| x**2 * y**5 | 6.099181e−21 |
| x**0 * y**7 | 4.964755e−22 |
| x**8 * y**0 | 8.516043e−22 |
| x**6 * y**2 | 5.099263e−23 |
| x**4 * y**4 | −2.898714e−24 |
| x**2 * y**6 | 5.952930e−25 |
| x**0 * y**8 | 5.163887e−25 |
| x**8 * y**1 | −9.316550e−25 |
| x**6 * y**3 | 1.299113e−26 |
| x**4 * y**5 | 1.951952e−26 |
| x**2 * y**7 | 1.175752e−26 |
| x**0 * y**9 | −1.324128e−28 |
| x**10 * y**0 | −5.593750e−27 |
| x**8 * y**2 | −2.861856e−28 |
| x**6 * y**4 | −6.110590e−29 |
| x**4 * y**6 | 4.287001e−29 |
| x**2 * y**8 | 1.439865e−29 |
| x**0 * y**10 | −7.857728e−31 |
| M4 | |
| RDX | 4607.556254 |
| RDY | −8743.538895 |
| CCX | 0.000000 |
| CCY | 0.000000 |
| x**i * y**j | Coefficient |
| x**2 * y**1 | −8.225314e−08 |
| x**0 * y**3 | 5.068497e−08 |
| x**4 * y**0 | 3.062945e−10 |
| x**2 * y**2 | 7.316096e−11 |
| x**0 * y**4 | −8.776456e−11 |
| x**4 * y**1 | −3.005486e−13 |
| x**2 * y**3 | −1.863037e−13 |
| x**0 * y**5 | 1.898828e−13 |
| x**6 * y**0 | 9.141514e−17 |
| x**4 * y**2 | 4.549265e−16 |
| x**2 * y**4 | 9.186901e−16 |
| x**0 * y**6 | −4.322991e−16 |
| x**6 * y**1 | −4.781174e−19 |
| x**4 * y**3 | −2.701629e−18 |
| x**2 * y**5 | −5.303339e−18 |
| x**0 * y**7 | 7.780527e−19 |
| x**8 * y**0 | −3.037275e−21 |
| x**6 * y**2 | 3.008955e−21 |
| x**4 * y**4 | 1.707917e−20 |
| x**2 * *y*6 | 1.973402e−20 |
| x**0 * y**8 | −9.203437e−22 |
| x**8 * y**1 | 4.271877e−24 |
| x**6 * y**3 | −1.853444e−23 |
| x**4 * y**5 | −5.292414e−23 |
| x**2 * y**7 | −3.676534e−23 |
| x**0 * y**9 | 6.430798e−25 |
| x**10 * y**0 | 2.950171e−26 |
| x**8 * y**2 | −4.038402e−27 |
| x**6 * y**4 | 3.962229e−26 |
| x**4 * y**6 | 5.778787e−26 |
| x**2 * y**8 | 2.626455e−26 |
| x**0 * y**10 | −2.242512e−28 |
| M5 | |
| RDX | −8515.086688 |
| RDY | 9595.599886 |
| CCX | 0.000000 |
| CCY | 0.000000 |
| x**i * y**j | Coefficient |
| x**2 * y**1 | −1.021063e−08 |
| x**0 * y**3 | −1.341784e−07 |
| x**4 * y**0 | −4.127338e−12 |
| x**2 * y**2 | −5.489398e−10 |
| x**0 * y**4 | −2.498626e−10 |
| x**4 * y**1 | −2.852403e−13 |
| x**2 * y**3 | 5.556293e−13 |
| x**0 * y**5 | 1.028605e−12 |
| x**6 * y**0 | −5.923089e−17 |
| x**4 * y**2 | 2.021479e−15 |
| x**2 * y**4 | −3.178041e−15 |
| x**0 * y**6 | −2.485901e−15 |
| x**6 * y**1 | 6.909088e−19 |
| x**4 * y**3 | −1.441991e−17 |
| x**2 * y**5 | −2.302546e−17 |
| x**0 * y**7 | −2.788828e−16 |
| x**8 * y**0 | 3.206142e−24 |
| x**6 * y**2 | −1.887775e−20 |
| x**4 * y**4 | −6.070998e−20 |
| x**2 * y**6 | −1.412123e−18 |
| x**0 * y**8 | −8.605460e−19 |
| x**8 * y**1 | 4.104945e−25 |
| x**6 * y**3 | −1.726424e−22 |
| x**4 * y**5 | −3.182963e−21 |
| x**2 * y**7 | −6.185073e−22 |
| x**0 * y**9 | 1.144665e−20 |
| x**10 * y**0 | 1.756733e−27 |
| x**8 * y**2 | 2.411810e−26 |
| x**6 * y**4 | −3.025338e−24 |
| x**4 * y**6 | −3.331273e−24 |
| x**2 * y**8 | 2.809004e−23 |
| x**0 * y**10 | 3.271562e−23 |
| M6 | |
| RDX | −1561.007639 |
| RDY | 13724.816968 |
| CCX | 0.000000 |
| CCY | 0.000000 |
| x**i * y**j | Coefficient |
| x**2 * y**1 | 2.983944e−07 |
| x**0 * y**3 | −7.389127e−08 |
| x**4 * y**0 | −2.527862e−10 |
| x**2 * y**2 | −2.346756e−10 |
| x**0 * y**4 | 5.379872e−10 |
| x**4 * y**1 | 1.972027e−13 |
| x**2 * y**3 | −9.497902e−14 |
| x**0 * y**5 | −8.840195e−13 |
| x**6 * y**0 | 4.398254e−18 |
| x**4 * y**2 | −9.973955e−16 |
| x**2 * y**4 | −2.087661e−15 |
| x**0 * y**6 | 1.007357e−14 |
| x**6 * y**1 | 1.514153e−19 |
| x**4 * y**3 | 3.402735e−18 |
| x**2 * y**5 | 1.221503e−17 |
| x**0 * y**7 | 6.426230e−17 |
| x**8 * y**0 | 2.000018e−21 |
| x**6 * y**2 | 1.327798e−22 |
| x**4 * y**4 | 1.962076e−20 |
| x**2 * y**6 | 2.254577e−20 |
| x**0 * y**8 | 8.722817e−19 |
| x**8 * y**1 | −4.757397e−24 |
| x**6 * y**3 | −1.071570e−23 |
| x**4 * y**5 | 4.678715e−23 |
| x**2 * y**7 | −1.923549e−21 |
| x**0 * y**9 | 5.477334e−21 |
| x**10 * y**0 | −2.136373e−26 |
| x**8 * y**2 | −9.660899e−27 |
| x**6 * y**4 | −3.918399e−25 |
| x**4 * y**6 | −8.181502e−25 |
| x**2 * y**8 | −1.492083e−23 |
| x**0 * y**10 | 2.234947e−23 |
| M7 | |
| RDX | 985.187285 |
| RDY | 577.682453 |
| CCX | 0.000000 |
| CCY | 0.000000 |
| x**i * y**j | Coefficient |
| x**2 * y**1 | −4.221187e−07 |
| x**0 * y**3 | −7.087330e−07 |
| x**4 * y**0 | 4.773979e−10 |
| x**2 * y**2 | 4.274766e−09 |
| x**0 * y**4 | −5.071565e−10 |
| x**4 * y**1 | −3.349265e−12 |
| x**2 * y**3 | −4.696164e−12 |
| x**0 * y**5 | −5.100248e−11 |
| x**6 * y**0 | 1.841036e−15 |
| x**4 * y**2 | 2.488233e−14 |
| x**2 * y**4 | 1.242376e−13 |
| x**0 * y**6 | 1.757040e−13 |
| x**6 * y**1 | −1.815868e−17 |
| x**4 * y**3 | −1.424643e−16 |
| x**2 * y**5 | −8.429020e−16 |
| x**0 * y**7 | 1.134581e−15 |
| x**8 * y**0 | 6.934470e−21 |
| x**6 * y**2 | 1.970444e−19 |
| x**4 * y**4 | 1.432653e−18 |
| x**2 * y**6 | −8.966157e−19 |
| x**0 * y**8 | 1.105551e−18 |
| x**8 * y**1 | −2.136276e−22 |
| x**6 * y**3 | −2.938632e−21 |
| x**4 * y**5 | −9.668625e−21 |
| x**2 * y**7 | 6.430791e−21 |
| x**0 * y**9 | 2.034125e−20 |
| x**10 * y**0 | 8.133413e−26 |
| x**8 * y**2 | 2.825289e−24 |
| x**6 * y**4 | 2.397173e−23 |
| x**4 * y**6 | 5.371385e−23 |
| x**2 * y**8 | −3.292094e−23 |
| x**0 * y**10 | −3.451419e−22 |
| M8 | |
| RDX | −1537.031629 |
| RDY | −1391.412955 |
| CCX | 0.000000 |
| CCY | 0.000000 |
| x**i * y**j | Coefficient |
| x**2 * y**1 | 1.432458e−09 |
| x**0 * y**3 | 5.841131e−09 |
| x**4 * y**0 | −4.067976e−12 |
| x**2 * y**2 | −1.030804e−11 |
| x**0 * y**4 | −1.913759e−12 |
| x**4 * y**1 | 9.897499e−16 |
| x**2 * y**3 | 4.103487e−15 |
| x**0 * y**5 | 6.629274e−15 |
| x**6 * y**0 | −1.929544e−18 |
| x**4 * y**2 | −7.015431e−18 |
| x**2 * y**4 | −6.828544e−18 |
| x**0 * y**6 | −3.676589e−18 |
| x**6 * y**1 | 2.046584e−22 |
| x**4 * y**3 | 1.907346e−21 |
| x**2 * y**5 | 3.658246e−21 |
| x**0 * y**7 | 4.661843e−21 |
| x**8 * y**0 | −8.111823e−25 |
| x**6 * y**2 | −4.080847e−24 |
| x**4 * y**4 | −5.057029e−24 |
| x**2 * y**6 | −3.279252e−24 |
| x**0 * y**8 | −2.338327e−24 |
| x**8 * y**1 | 1.303246e−27 |
| x**6 * y**3 | 5.870146e−27 |
| x**4 * y**5 | 4.731851e−27 |
| x**2 * y**7 | 2.235796e−27 |
| x**0 * y**9 | −1.157629e−26 |
| x**10 * y**0 | −4.079542e−31 |
| x**8 * y**2 | −1.433605e−30 |
| x**6 * y**4 | −3.951554e−30 |
| x**4 * y**6 | −8.437097e−30 |
| x**2 * y**8 | 2.945539e−30 |
| x**0 * y**10 | 8.760649e−30 |
| x**10 * y**1 | −1.964756e−33 |
| x**8 * y**3 | −1.046456e−32 |
| x**6 * y**5 | −1.343333e−32 |
| x**4 * y**7 | 4.957374e−33 |
| x**2 * y**9 | 1.272612e−32 |
| x**0 * y**11 | 2.094888e−32 |
| x**12 * y**0 | −2.974136e−37 |
| x**10 * y**2 | −3.028238e−36 |
| x**8 * y**4 | −1.106608e−35 |
| x**6 * y**6 | −7.744168e−36 |
| x**4 * y**8 | −3.288303e−36 |
| x**2 * y**10 | −2.070242e−35 |
| x**0 * y**12 | −8.200759e−36 |

TABLE 5 for FIG. 3

| Mirrors | Reflectivity |
|---|---|
| M8 | 0.674897 |
| M7 | 0.645442 |
| M6 | 0.825635 |
| M5 | 0.835327 |
| M4 | 0.887578 |
| M3 | 0.924327 |
| M2 | 0.697153 |
| M1 | 0.707727 |
| Overall transmission | 0.121609 |

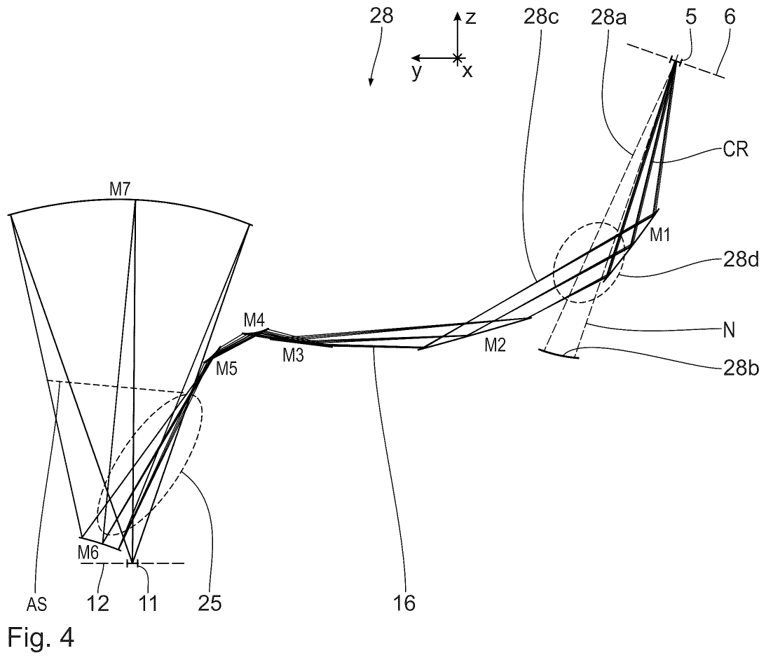

FIG. 4 shows a further embodiment of a projection optical unit or imaging optical unit 28, which can be used in the projection exposure apparatus 1 instead of the projection optical unit 10 of the embodiment according to FIG. 2. Components and functions corresponding to those which have already been explained above in conjunction with FIGS. 1 to 3, and in particular in conjunction with FIGS. 2 and 3, are denoted by the same reference signs and are not discussed in detail again.

In the beam path of the imaging light 16 downstream of the object field 5, the projection optical unit 28 initially has three GI mirrors M1, M2, M3 which add in terms of their deflective effect such that an overall deflection effect of slightly more than 90° arises. This is subsequently followed by two further GI mirrors M4 and M5 with a deflection effect which in turn is added and is counter to that of the GI mirrors M1 to M3. An overall deflection effect of the GI mirrors M4 and M5 is approximately 75°. This is subsequently followed by two further NI mirrors M6 and M7, the basic arrangement of which is comparable to the two penultimate mirrors of the projection optical units 10 and 27 described above. Thus, the projection optical unit 28 has five GI mirrors M1 to M5 and two NI mirrors M6 and M7.

In the case of the projection optical unit 28, a chief ray CR of a central field point starting at the object field 5 runs, in relation to a normal N of this central field point of the object field 5 and initially in relation to a plane (xN) formed by each normal N and an axis parallel to the x-axis, in a different half-space, which extends to the right of the normals N in FIG. 4, in comparison with the arrangement positions of the mirrors M2ff.

This leads to, firstly, an illumination/imaging beam path section 28a between a last component 28b of the illumination optical unit 4, indicated as a mirror in FIG. 4, and the object field 5 and, secondly, an illumination/imaging light beam path section 28c between the first two mirrors M1 and M2 of the projection optical unit 28 crossing in a crossing region 28d. Thus, the illumination/imaging beam path section 28a between one of the last components (component 28b) of the illumination optical unit 4 and the object field 5 and an illumination/imaging beam path section 28c between the object field 5 and one of the first components (beam path section between mirrors M1 and M2) of the imaging optical unit 28 cross in the crossing region 28d.

Additionally, in comparison with the other mirrors M2ff, the mirror M1 is located in the other half-space in relation to this xN-plane.

The following tables summarize parameters and the optical design of the projection optical unit 28. In terms of their structure, these tables correspond to those already explained above in conjunction with FIG. 2.

TABLE 1 for FIG. 4

| | |
|---|---|
| Wavelength | 13.5 nm |
| Image-side aperture | 0.33 |
| β | −4.00 |
| Chief ray angle | 6.05° |
| Étendue | 7.08 mm² |
| Mean wavefront aberration RMS | 30.88 mλ |
| Overall transmission | 11.90% |
| Position of the entrance pupil (x) | 5065.79 mm |
| Position of the entrance pupil (y) | 26362.45 mm |
| Object-image offset in the y-direction | 2481.53 mm |
| Image field size (x) | 26 mm |
| Image field size (y) | 2.5 mm |
| Distance between M6 and image plane | 56 mm |
| Distance between the object plane and | 2290.21 mm |
| image plane | |
| Tilt between the object and | 19.3° |
| image plane | |
| Installation space cuboid | (1115 × 2935 × 1588) mm |

TABLE 2a for FIG. 4

| | M1 | M2 | M3 | M4 |
|---|---|---|---|---|
| Maximum angle of incidence [°] | 68.0 | 79.2 | 84.0 | 69.6 |
| Minimum angle of incidence [°] | 64.0 | 74.0 | 77.9 | 64.0 |
| Extent of the reflection surface | 231.8 | 350.4 | 479.8 | 524.9 |
| in the x-direction [mm] | | | | |
| Extent of the reflection surface | 384.2 | 515.3 | 265.1 | 99.9 |
| in the y-direction [mm] | | | | |
| Maximum mirror diameter [mm] | 393.3 | 521.9 | 481.1 | 525.5 |

TABLE 2b for FIG. 4

| | M5 | M6 | M7 |
|---|---|---|---|
| Maximum angle of incidence [°] | 80.1 | 24.0 | 5.5 |
| Minimum angle of incidence [°] | 70.5 | 1.9 | 1.3 |
| Extent of the reflection surface | 540.9 | 578.4 | 1114.7 |
| in the x-direction [mm] | | | |
| Extent of the reflection surface | 82.3 | 179.0 | 1090.2 |
| in the y-direction [mm] | | | |
| Maximum mirror diameter [mm] | 541.2 | 578.4 | 1114.7 |

TABLE 3a for FIG. 4

| | y-distance | z-distance | Tilt about the |
|---|---|---|---|
| | [mm] | [mm] | x-axis [degrees] |
| Object field | 2617.613579 | 2897.162348 | 0.000000 |
| M1 | 2538.995709 | 2080.684552 | 246.834158 |
| M2 | 2086.772773 | 1557.364578 | 34.360602 |
| M3 | 1015.810934 | 1177.004195 | 185.384997 |
| M4 | 670.383832 | 1230.373545 | 11.919326 |
| M5 | 447.145957 | 1087.488653 | 46.011129 |
| M6 | −138.535923 | 97.126614 | −17.756720 |
| M7 | 0.000000 | 1708.401781 | −2.457076 |
| Stop (AS) | −78.335286 | 797.304506 | −4.914152 |
| Image field | 0.000000 | 0.000000 | −0.000000 |

TABLE 3b for FIG. 4

| | y-distance | Tilt about the y- | Tilt about the |
|---|---|---|---|
| | [mm] | axis [degrees] | z-axis [degrees] |
| Object field | 2617.613579 | 0.00 | 180.00 |
| M1 | 2538.995709 | 0.00 | −0.00 |
| M2 | 2086.772773 | 180.00 | 0.00 |
| M3 | 1015.810934 | 0.00 | −0.00 |
| M4 | 670.383832 | 0.00 | 180.00 |
| M5 | 447.145957 | 0.00 | −0.00 |
| M6 | −138.535923 | 180.00 | 0.00 |
| M7 | 0.000000 | 0.00 | −0.00 |
| Stop (AS) | −78.335286 | 180.00 | 0.00 |
| Image field | 0.000000 | 0.00 | −0.00 |

TABLE 4 for FIG. 4

| | |
|---|---|
| M1 | |
| RDX | −6022.044874 |
| RDY | −6151.193878 |
| CCX | 0.000000 |
| CCY | 0.000000 |
| x**i * y**j | Coefficient |
| x**2 * y**1 | −4.359830e−08 |
| x**0 * y**3 | 1.753754e−08 |
| x**4 * y**0 | −1.308429e−11 |
| x**2 * y**2 | −1.666187e−11 |
| x**0 * y**4 | −2.738503e−11 |
| x**4 * y**1 | −3.173120e−14 |
| x**2 * y**3 | −6.246259e−15 |
| x**0 * y**5 | 1.509583e−14 |
| x**6 * y**0 | 2.531883e−16 |
| x**4 * y**2 | 4.403745e−17 |
| x**2 * y**4 | 3.911238e−17 |
| x**0 * y**6 | −6.642873e−17 |
| x**6 * y**1 | 1.784220e−18 |
| x**4 * y**3 | 8.267175e−19 |
| x**2 * y**5 | 2.745811e−19 |
| x**0 * y**7 | −1.046170e−19 |
| x**8 * y**0 | −5.739054e−20 |
| x**6 * y**2 | −2.571995e−20 |
| x**4 * y**4 | −2.887711e−21 |
| x**2 * y**6 | −1.538535e−22 |
| x**0 * y**8 | −7.380270e−23 |
| x**8 * y**1 | −2.063032e−22 |
| x**6 * y**3 | −1.107641e−22 |
| x**4 * y**5 | −2.855709e−23 |
| x**2 * y**7 | −7.410164e−24 |
| x**0 * y**9 | 4.052050e−24 |
| x**10 * y**0 | 5.264334e−24 |
| x**8 * y**2 | 3.139515e−24 |
| x**6 * y**4 | 8.268862e−25 |
| x**4 * y**6 | 6.523616e−26 |
| x**2 * y**8 | 2.052319e−26 |
| x**0 * y**10 | −1.367309e−26 |
| x**10 * y**1 | 9.438779e−27 |
| x**8 * y**3 | 6.973530e−27 |
| x**6 * y**5 | 2.382623e−27 |
| x**4 * y**7 | 6.164347e−28 |
| x**2 * y**9 | 1.566279e−28 |
| x**0 * y**11 | −8.481061e−29 |
| x**12 * y**0 | −2.336153e−28 |
| x**10 * y**2 | −1.833850e−28 |
| x**8 * y**4 | −6.777491e−29 |
| x**6 * y**6 | −1.125688e−29 |
| x**4 * y**8 | −9.777818e−31 |
| x**2 * y**10 | −4.313483e−31 |
| x**0 * y**12 | 2.795925e−31 |
| x**12 * y**1 | −1.438995e−31 |
| x**10 * y**3 | −1.520849e−31 |
| x**8 * y**5 | −6.630891e−32 |
| x**6 * y**7 | −2.111666e−32 |
| x**4 * y**9 | −5.845336e−33 |
| x**2 * y**11 | −1.024570e−33 |
| x**0 * y**13 | 6.563092e−34 |
| x**14 * y**0 | 4.084101e−33 |
| x**12 * y**2 | 4.015212e−33 |
| x**10 * y**4 | 1.871066e−33 |
| x**8 * y**6 | 4.597435e−34 |
| x**6 * y**8 | 7.070175e−35 |
| x**4 * y**10 | 1.144414e−35 |
| x**2 * y**12 | 3.592714e−36 |
| x**0 * y**14 | −2.533151e−36 |
| M2 | |
| RDX | 6839.268518 |
| RDY | −9685.117345 |
| CCX | 0.000000 |
| CCY | 0.000000 |
| x**i * y**j | Coefficient |
| x**2 * y**1 | −9.995847e−08 |
| x**0 * y**3 | 2.621991e−08 |
| x**4 * y**0 | −5.815399e−11 |
| x**2 * y**2 | 5.484343e−11 |
| x**0 * y**4 | −1.154406e−11 |
| x**4 * y**1 | 3.693228e−14 |
| x**2 * y**3 | −5.451156e−14 |
| x**0 * y**5 | 2.912616e−14 |
| x**6 * y**0 | 1.483880e−16 |
| x**4 * y**2 | −4.486027e−17 |
| x**2 * y**4 | 1.272432e−16 |
| x**0 * y**6 | 8.827984e−18 |
| x**6 * y**1 | −3.561112e−19 |
| x**4 * y**3 | 3.364003e−20 |
| x**2 * y**5 | −1.021464e−19 |
| x**0 * y**7 | −1.455992e−20 |
| x**8 * y**0 | −7.030263e−21 |
| x**6 * y**2 | −3.652954e−21 |
| x**4 * y**4 | −1.801149e−21 |
| x**2 * y**6 | −3.466084e−22 |
| x**0 * y**8 | −1.904075e−23 |
| x**8 * y**1 | 3.346482e−23 |
| x**6 * y**3 | 7.958264e−24 |
| x**4 * y**5 | 3.213513e−24 |
| x**2 * y**7 | 1.241671e−24 |
| x**0 * y**9 | 1.270350e−24 |
| x**10 * y**0 | 4.313113e−25 |
| x**8 * y**2 | 3.284227e−25 |
| x**6 * y**4 | 1.211272e−25 |
| x**4 * y**6 | 3.574127e−26 |
| x**2 * y**8 | 1.108107e−26 |
| x**0 * y**10 | 2.385952e−27 |
| x**10 * y**1 | −1.126172e−27 |
| x**8 * y**3 | −8.873078e−29 |
| x**6 * y**5 | −1.234919e−28 |
| x**4 * y**7 | −4.685468e−29 |
| x**2 * y**9 | −1.359490e−29 |
| x**0 * y**11 | −1.009751e−29 |
| x**12 * y**0 | −1.358738e−29 |
| x**10 * y**2 | −1.093876e−29 |
| x**8 * y**4 | −4.438986e−30 |
| x**6 * y**6 | −1.819889e−30 |
| x**4 * y**8 | −4.363670e−31 |
| x**2 * y**10 | −1.044487e−31 |
| x**0 * y**12 | −2.276102e−32 |
| x**12 * y**1 | 1.436185e−32 |
| x**10 * y**3 | −2.425574e−33 |
| x**8 * y**5 | 1.310690e−34 |
| x**6 * y**7 | 9.036943e−34 |
| x**4 * y**9 | 2.582823e−34 |
| x**2 * y**11 | 6.920985e−35 |
| x**0 * y**13 | 4.538543e−35 |
| x**14 * y**0 | 1.599812e−34 |
| x**12 * y**2 | 1.345811e−34 |
| x**10 * y**4 | 4.859574e−35 |
| x**8 * y**6 | 2.870601e−35 |
| x**6 * y**8 | 9.732914e−36 |
| x**4 * y**10 | 1.914379e−36 |
| x**2 * y**12 | 4.323017e−37 |
| x**0 * y**14 | 1.083771e−37 |
| M3 | |
| RDX | 1076.063864 |
| RDY | −21046.272844 |
| CCX | 0.000000 |
| CCY | 0.000000 |
| x**i * y**j | Coefficient |
| x**2 * y**1 | −2.810350e−07 |
| x**0 * y**3 | −1.742288e−07 |
| x**4 * y**0 | 1.333828e−10 |
| x**2 * y**2 | 5.467360e−10 |
| x**0 * y**4 | 5.661242e−11 |
| x**4 * y**1 | −7.819822e−13 |
| x**2 * y**3 | −1.028978e−12 |
| x**0 * y**5 | −4.778648e−13 |
| x**6 * y**0 | 2.358496e−16 |
| x**4 * y**2 | 2.527667e−15 |
| x**2 * y**4 | 2.887721e−15 |
| x**0 * y**6 | 4.583351e−16 |
| x**6 * y**1 | −1.705771e−18 |
| x**4 * y**3 | −8.089034e−18 |
| x**2 * y**5 | −7.239544e−18 |
| x**0 * y**7 | −8.399193e−18 |
| x**8 * y**0 | 1.011450e−21 |
| x**6 * y**2 | 1.118888e−20 |
| x**4 * y**4 | 2.160795e−20 |
| x**2 * y**6 | 2.971218e−20 |
| x**0 * y**8 | −2.147604e−20 |
| x**8 * y**1 | −2.865200e−23 |
| x**6 * y**3 | −5.262215e−23 |
| x**4 * y**5 | −1.312682e−22 |
| x**2 * y**7 | 3.103055e−22 |
| x**0 * y**9 | 1.103882e−21 |
| x**10 * y**0 | −3.168396e−27 |
| x**8 * y**2 | 7.154729e−26 |
| x**6 * y**4 | 4.839326e−25 |
| x**4 * y**6 | 1.303379e−25 |
| x**2 * y**8 | −3.319774e−24 |
| x**0 * y**10 | 7.940533e−24 |
| x**10 * y**1 | 3.050581e−28 |
| x**8 * y**3 | −5.215936e−28 |
| x**6 * y**5 | −1.623675e−28 |
| x**4 * y**7 | 4.908679e−27 |
| x**2 * y**9 | −7.201781e−26 |
| x**0 * y**11 | −3.661229e−26 |
| x**12 * y**0 | 3.119869e−32 |
| x**10 * y**2 | −2.539567e−31 |
| x**8 * y**4 | −1.342215e−30 |
| x**6 * y**6 | −2.476014e−29 |
| x**4 * y**8 | 1.681520e−28 |
| x**2 * y**10 | −9.529436e−29 |
| x**0 * y**12 | −3.518712e−28 |
| x**12 * y**1 | −2.301309e−33 |
| x**10 * y**3 | 2.352859e−33 |
| x**8 * y**5 | 2.133444e−32 |
| x**6 * y**7 | −1.675453e−31 |
| x**4 * y**9 | 6.826927e−31 |
| x**2 * y**11 | 1.758727e−30 |
| x**0 * y**13 | 4.315241e−31 |
| x**14 * y**0 | 4.929847e−37 |
| x**12 * y**2 | 4.718446e−36 |
| x**10 * y**4 | −2.562073e−35 |
| x**8 * y**6 | 2.649479e−34 |
| x**6 * y**8 | −9.401007e−34 |
| x**4 * y**10 | −3.089305e−33 |
| x**2 * y**12 | 3.552945e−33 |
| x**0 * y**14 | 5.104003e−33 |
| M4 | |
| RDX | −1370.961067 |
| RDY | −3298.925130 |
| CCX | 0.000000 |
| CCY | 0.000000 |
| x**i * y**j | Coefficient |
| x**2 * y**1 | 2.800494e−07 |
| x**0 * y**3 | 1.189568e−07 |
| x**4 * y**0 | −7.740937e−11 |
| x**2 * y**2 | −2.317791e−10 |
| x**0 * y**4 | 6.089350e−10 |
| x**4 * y**1 | 2.862300e−13 |
| x**2 * y**3 | 2.953048e−14 |
| x**0 * y**5 | 6.966254e−12 |
| x**6 * y**0 | −7.081041e−17 |
| x**4 * y**2 | −5.403479e−16 |
| x**2 * y**4 | −7.304828e−15 |
| x**0 * y**6 | 1.107454e−13 |
| x**6 * y**1 | 1.653990e−19 |
| x**4 * y**3 | 4.364237e−18 |
| x**2 * y**5 | −1.670857e−16 |
| x**0 * y**7 | −1.613173e−15 |
| x**8 * y**0 | 1.836414e−23 |
| x**6 * y**2 | −2.585855e−21 |
| x**4 * y**4 | 1.212040e−19 |
| x**2 * y**6 | 2.080202e−18 |
| x**0 * y**8 | −8.347715e−17 |
| x**8 * y**1 | 5.146889e−24 |
| x**6 * y**3 | −5.873341e−23 |
| x**4 * y**5 | −1.882196e−21 |
| x**2 * y**7 | 1.580817e−19 |
| x**0 * y**9 | 5.826956e−19 |
| x**10 * y**0 | −1.542377e−27 |
| x**8 * y**2 | 3.939218e−26 |
| x**6 * y**4 | 5.862114e−25 |
| x**4 * y**6 | −1.364258e−22 |
| x**2 * y**8 | 9.719638e−25 |
| x**0 * y**10 | 3.248335e−20 |
| x**10 * y**1 | −4.286089e−29 |
| x**8 * y**3 | −2.150550e−28 |
| x**6 * y**5 | 6.969220e−26 |
| x**4 * y**7 | 8.450910e−26 |
| x**2 * y**9 | −6.497028e−23 |
| x**0 * y**11 | −1.313558e−22 |
| x**12 * y**0 | 1.315631e−32 |
| x**10 * y**2 | −3.162774e−31 |
| x**8 * y**4 | −1.286320e−29 |
| x**6 * y**6 | 6.518244e−29 |
| x**4 * y**8 | 4.846687e−26 |
| x**2 * y**10 | −1.689430e−25 |
| x**0 * y**12 | −4.074139e−24 |
| x**12 * y**1 | 1.507759e−34 |
| x**10 * y**3 | 5.499076e−33 |
| x**8 * y**5 | 2.351498e−32 |
| x**6 * y**7 | −3.145581e−29 |
| x**4 * y**9 | 2.173238e−28 |
| x**2 * y**11 | 8.888697e−27 |
| x**0 * y**13 | 2.538366e−26 |
| x**14 * y**0 | −6.417929e−38 |
| x**12 * y**2 | 1.225831e−36 |
| x**10 * y**4 | −1.120307e−34 |
| x**8 * y**6 | 6.331036e−33 |
| x**6 * y**8 | 9.559200e−32 |
| x**4 * y**10 | −5.082977e−30 |
| x**2 * y**12 | −1.043617e−29 |
| x**0 * y**14 | −1.075075e−28 |
| M5 | |
| RDX | −4998.576664 |
| RDY | 5447.179645 |
| CCX | 0.000000 |
| CCY | 0.000000 |
| x**i * y**j | Coefficient |
| x**2 * y**1 | 1.515989e−07 |
| x**0 * y**3 | −3.250054e−08 |
| x**4 * y**0 | 5.539109e−11 |
| x**2 * y**2 | 4.748234e−11 |
| x**0 * y**4 | −2.233383e−10 |
| x**4 * y**1 | 1.254932e−13 |
| x**2 * y**3 | −7.666036e−13 |
| x**0 * y**5 | −1.220062e−12 |
| x**6 * y**0 | 4.574711e−17 |
| x**4 * y**2 | −8.240937e−16 |
| x**2 * y**4 | −4.293733e−15 |
| x**0 * y**6 | −5.085227e−15 |
| x**6 * y**1 | −1.609272e−19 |
| x**4 * y**3 | −6.444357e−18 |
| x**2 * y**5 | −2.107933e−17 |
| x**0 * y**7 | −2.104762e−17 |
| x**8 * y**0 | −2.786721e−23 |
| x**6 * y**2 | −3.982201e−21 |
| x**4 * y**4 | −3.415767e−20 |
| x**2 * y**6 | −9.925500e−20 |
| x**0 * y**8 | −1.024091e−19 |
| x**8 * y**1 | −4.181780e−24 |
| x**6 * y**3 | −1.759230e−23 |
| x**4 * y**5 | −1.285656e−22 |
| x**2 * y**7 | −4.649591e−22 |
| x**0 * y**9 | −9.205944e−22 |
| x**10 * y**0 | −1.028975e−27 |
| x**8 * y**2 | −1.806308e−26 |
| x**6 * y**4 | −1.247949e−25 |
| x**4 * y**6 | −4.320972e−25 |
| x**2 * y**8 | −2.071994e−24 |
| x**0 * y**10 | −5.061803e−24 |
| x**10 * y**1 | 1.359972e−29 |
| x**8 * y**3 | −2.827423e−28 |
| x**6 * y**5 | −1.742472e−27 |
| x**4 * y**7 | −4.389750e−27 |
| x**2 * y**9 | 8.514759e−27 |
| x**0 * y**11 | 3.313946e−26 |
| x**12 * y**0 | 7.392378e−33 |
| x**10 * y**2 | −1.102466e−31 |
| x**8 * y**4 | −1.824503e−30 |
| x**6 * y**6 | −1.454001e−29 |
| x**4 * y**8 | −2.796006e−29 |
| x**2 * y**10 | 2.056926e−28 |
| x**0 * y**12 | 6.253987e−28 |
| x**12 * y**1 | −7.848736e−35 |
| x**10 * y**3 | 2.958145e−34 |
| x**8 * y**5 | −3.869160e−33 |
| x**6 * y**7 | −5.250018e−32 |
| x**4 * y**9 | −2.954661e−32 |
| x**2 * y**11 | 9.186617e−31 |
| x**0 * y**13 | 3.282384e−30 |
| x**14 * y**0 | −2.968699e−38 |
| x**12 * y**2 | 3.105981e−37 |
| x**10 * y**4 | 2.755519e−36 |
| x**8 * y**6 | 1.021245e−36 |
| x**6 * y**8 | −4.694652e−35 |
| x**4 * y**10 | 1.249056e−34 |
| x**2 * y**12 | 8.472723e−34 |
| x**0 * y**14 | 6.311045e−33 |
| M6 | |
| RDX | 3970.682005 |
| RDY | 1090.488372 |
| CCX | 0.000000 |
| CCY | 0.000000 |
| x**i * y**j | Coefficient |
| x**2 * y**1 | −2.339788e−07 |
| x**0 * y**3 | 3.062861e−07 |
| x**4 * y**0 | 5.593089e−11 |
| x**2 * y**2 | 2.178406e−10 |
| x**0 * y**4 | 5.992996e−10 |
| x**4 * y**1 | −2.148197e−13 |
| x**2 * y**3 | −4.652973e−14 |
| x**0 * y**5 | 2.079211e−12 |
| x**6 * y**0 | 3.571626e−17 |
| x**4 * y**2 | 3.484457e−16 |
| x**2 * y**4 | −3.747067e−16 |
| x**0 * y**6 | 2.126847e−15 |
| x**6 * y**1 | −2.330367e−19 |
| x**4 * y**3 | 1.625092e−20 |
| x**2 * y**5 | 7.007978e−19 |
| x**0 * y**7 | 1.969341e−17 |
| x**8 * y**0 | 1.992574e−23 |
| x**6 * y**2 | 1.251042e−22 |
| x**4 * y**4 | −1.278408e−21 |
| x**2 * y**6 | −9.476191e−21 |
| x**0 * y**8 | 1.095020e−19 |
| x**8 * y**1 | −2.186461e−25 |
| x**6 * y**3 | −4.159235e−24 |
| x**4 * y**5 | 5.056679e−24 |
| x**2 * y**7 | −1.352631e−22 |
| x**0 * y**9 | 6.316251e−23 |
| x**10 * y**0 | 1.668553e−28 |
| x**8 * y**2 | 9.105553e−27 |
| x**6 * y**4 | 6.580729e−26 |
| x**4 * y**6 | 2.796208e−25 |
| x**2 * y**8 | −4.945124e−25 |
| x**0 * y**10 | −5.348054e−24 |
| x**10 * y**1 | −1.117431e−31 |
| x**8 * y**3 | 6.919770e−29 |
| x**6 * y**5 | 2.184470e−28 |
| x**4 * y**7 | −5.979367e−28 |
| x**2 * y**9 | 1.326032e−26 |
| x**0 * y**11 | 1.222603e−26 |
| x**12 * y**0 | −8.869146e−34 |
| x**10 * y**2 | −8.084286e−32 |
| x**8 * y**4 | −1.129105e−30 |
| x**6 * y**6 | −6.514322e−30 |
| x**4 * y**8 | −2.569663e−29 |
| x**2 * y**10 | 7.572863e−30 |
| x**0 * y**12 | 7.919210e−30 |
| x**12 * y**1 | −3.374402e−36 |
| x**10 * y**3 | −4.266026e−34 |
| x**8 * y**5 | −2.968627e−33 |
| x**6 * y**7 | 7.983826e−34 |
| x**4 * y**9 | 5.959706e−32 |
| x**2 * y**11 | −3.239608e−31 |
| x**0 * y**13 | −3.932216e−31 |
| x**14 * y**0 | 3.093117e−39 |
| x**12 * y**2 | 3.365922e−37 |
| x**10 * y**4 | 6.763241e−36 |
| x**8 * y**6 | 5.434381e−35 |
| x**6 * y**8 | 2.082429e−34 |
| x**4 * y**10 | 7.434201e−34 |
| x**2 * y**12 | −7.244599e−34 |
| x**0 * y**14 | 2.013395e−33 |
| M7 | |
| RDX | −2295.336411 |
| RDY | −1844.166643 |
| CCX | 0.000000 |
| CCY | 0.000000 |
| x**i * y**j | Coefficient |
| x**2 * y**1 | 8.329363e−09 |
| x**0 * y**3 | −1.570214e−09 |
| x**4 * y**0 | −1.771610e−12 |
| x**2 * y**2 | −3.966989e−12 |
| x**0 * y**4 | −5.981146e−13 |
| x**4 * y**1 | 1.979474e−15 |
| x**2 * y**3 | 1.230814e−15 |
| x**0 * y**5 | −4.067206e−16 |
| x**6 * y**0 | −3.964893e−19 |
| x**4 * y**2 | −1.780559e−18 |
| x**2 * y**4 | −1.584997e−18 |
| x**0 * y**6 | −1.645571e−19 |
| x**6 * y**1 | 4.861763e−22 |
| x**4 * y**3 | 8.808525e−22 |
| x**2 * y**5 | 4.417499e−22 |
| x**0 * y**7 | −4.962963e−22 |
| x**8 * y**0 | 8.768270e−26 |
| x**6 * y**2 | 1.427108e−24 |
| x**4 * y**4 | 2.081026e−24 |
| x**2 * y**6 | 5.939373e−25 |
| x**0 * y**8 | 3.218226e−25 |
| x**8 * y**1 | −3.009925e−28 |
| x**6 * y**3 | −1.318691e−27 |
| x**4 * y**5 | −1.934132e−27 |
| x**2 * y**7 | −1.384139e−28 |
| x**0 * y**9 | 1.549665e−27 |
| x**10 * y**0 | −7.527227e−31 |
| x**8 * y**2 | −1.440493e−29 |
| x**6 * y**4 | −3.528172e−29 |
| x**4 * y**6 | −2.694551e−29 |
| x**2 * y**8 | −7.379039e−30 |
| x**0 * y**10 | −2.673449e−30 |
| x**10 * y**1 | 1.249653e−33 |
| x**8 * y**3 | 7.171222e−33 |
| x**6 * y**5 | 1.613513e−32 |
| x**4 * y**7 | 1.198686e−32 |
| x**2 * y**9 | 4.015148e−34 |
| x**0 * y**11 | −5.580335e−33 |
| x**12 * y**0 | 2.025902e−36 |
| x**10 * y**2 | 5.598396e−35 |
| x**8 * y**4 | 1.964698e−34 |
| x**6 * y**6 | 2.373219e−34 |
| x**4 * y**8 | 1.160415e−34 |
| x**2 * y**10 | 2.531804e−35 |
| x**0 * y**12 | 1.195760e−35 |
| x**12 * y**1 | −2.098419e−39 |
| x**10 * y**3 | −1.640894e−38 |
| x**8 * y**5 | −5.010745e−38 |
| x**6 * y**7 | −5.857987e−38 |
| x**4 * y**9 | −2.938110e−38 |
| x**2 * y**11 | 1.173577e−39 |
| x**0 * y**13 | 7.831128e−39 |
| x**14 * y**0 | −3.036170e−42 |
| x**12 * y**2 | −1.116503e−40 |
| x**10 * y**4 | −5.186957e−40 |
| x**8 * y**6 | −8.791787e−40 |
| x**6 * y**8 | −6.768868e−40 |
| x**4 * y**10 | −2.438044e−40 |
| x**2 * y**12 | −4.808899e−41 |
| x**0 * y**14 | −2.146562e−41 |
| x**14 * y**1 | 1.435783e−45 |
| x**12 * y**3 | 1.513158e−44 |
| x**10 * y**5 | 5.778385e−44 |
| x**8 * y**7 | 9.289158e−44 |
| x**6 * y**9 | 7.230514e−44 |
| x**4 * y**11 | 2.780128e−44 |
| x**2 * y**13 | −2.384354e−45 |
| x**0 * y**15 | −4.742498e−45 |
| x**16 * y**0 | 1.861992e−48 |
| x**14 * y**2 | 8.852231e−47 |
| x**12 * y**4 | 5.169585e−46 |
| x**10 * y**6 | 1.149013e−45 |
| x**8 * y**8 | 1.232166e−45 |
| x**6 * y**10 | 6.939880e−46 |
| x**4 * y**12 | 1.986361e−46 |
| x**2 * y**14 | 3.882393e−47 |
| x**0 * y**16 | 1.552441e−47 |

TABLE 5 for FIG. 4

| Mirrors | Reflectivity |
|---|---|
| M7 | 0.677606 |
| M6 | 0.662439 |
| M5 | 0.804769 |
| M4 | 0.722823 |
| M3 | 0.792973 |
| M2 | 0.783720 |
| M1 | 0.749441 |
| Overall transmission | 0.121614 |

TABLE 6 for FIG. 4

| x [mm] | y [mm] | z [mm] |
|---|---|---|
| −0.000 | 314.157 | 0.000 |
| −83.603 | 308.604 | 0.000 |
| −164.035 | 292.092 | 0.000 |
| −238.216 | 265.064 | 0.000 |
| −303.257 | 228.270 | 0.000 |
| −356.576 | 182.779 | 0.000 |
| −396.028 | 129.988 | 0.000 |
| −420.032 | 71.622 | 0.000 |
| −427.666 | 9.715 | 0.000 |
| −418.715 | −53.430 | 0.000 |
| −393.655 | −115.317 | 0.000 |
| −353.591 | −173.369 | 0.000 |
| −300.171 | −225.059 | 0.000 |
| −235.494 | −268.060 | 0.000 |
| −162.032 | −300.373 | 0.000 |
| −82.548 | −320.436 | 0.000 |
| 0.000 | −327.241 | 0.000 |
| 82.548 | −320.436 | 0.000 |
| 162.032 | −300.373 | 0.000 |
| 235.494 | −268.060 | 0.000 |
| 300.171 | −225.059 | 0.000 |
| 353.591 | −173.369 | 0.000 |
| 393.655 | −115.317 | 0.000 |
| 418.715 | −53.430 | 0.000 |
| 427.666 | 9.715 | 0.000 |
| 420.032 | 71.622 | 0.000 |
| 396.028 | 129.988 | 0.000 |
| 356.576 | 182.779 | 0.000 |
| 303.257 | 228.270 | 0.000 |
| 238.216 | 265.064 | 0.000 |
| 164.035 | 292.092 | 0.000 |
| 83.603 | 308.604 | 0.000 |

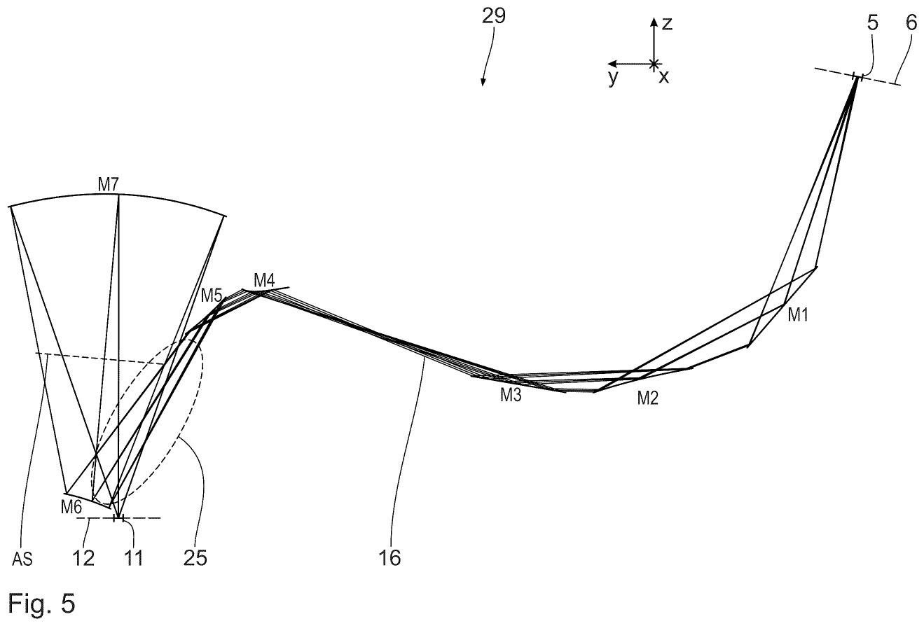

FIG. 5 shows a further embodiment of a projection optical unit or imaging optical unit 29, which can be used in the projection exposure apparatus 1 instead of the projection optical unit 10 of the embodiment according to FIG. 2. Components and functions corresponding to those which have already been explained above in conjunction with FIGS. 1 to 4, and in particular in conjunction with FIGS. 2 to 4, are denoted by the same reference signs and are not discussed in detail again.

The basic structure of the projection optical unit 29 with initially five GI mirrors M1 to M5 and subsequently two further NI mirrors M6 and M7 corresponds to that of the projection optical unit 28 according to FIG. 4. The projection optical unit 29 has a significantly greater extent in the y-direction than the projection optical unit 28, with the result that a y-distance between the mirrors M3 and M4, in particular, is significantly greater in the case of the projection optical unit 29 than in the case of the projection optical unit 28 according to FIG. 4.

The following tables summarize parameters and the optical design of the projection optical unit 29. In terms of their structure, these tables correspond to those already explained above in conjunction with FIG. 2.

TABLE 1 for FIG. 5

| | |
|---|---|
| Wavelength | 13.5 nm |
| Image-side aperture | 0.33 |
| β | −4.00 |
| Chief ray angle | 5.91° |
| Étendue | 7.08 mm² |
| Mean wavefront aberration RMS | 36.14 mλ |
| Overall transmission | 11.45% |
| Position of the entrance pupil (x) | 132329.75 mm |
| Position of the entrance pupil (y) | 956.05 mm |
| Object-image offset in the y-direction | 3841.37 mm |
| Image field size (x) | 26 mm |
| Image field size (y) | 2.5 mm |
| Distance between M6 and image plane | 50 mm |
| Distance between the object plane and | 2298.27 mm |
| image plane | |
| Tilt between the object and | 11.3° |
| Image plane | |
| Installation space cuboid | (1138 × 4186 × 1627) mm |

TABLE 2a for FIG. 5

| | M1 | M2 | M3 | M4 |
|---|---|---|---|---|
| Maximum angle of incidence [°] | 67.6 | 81.1 | 82.0 | 69.7 |
| Minimum angle of incidence [°] | 65.0 | 73.4 | 76.6 | 64.0 |
| Extent of the reflection surface | 312.6 | 401.9 | 463.0 | 698.7 |
| in the x-direction [mm] | | | | |
| Extent of the reflection surface | 540.9 | 513.7 | 478.0 | 224.8 |
| in the y-direction [mm] | | | | |
| Maximum mirror diameter [mm] | 547.2 | 522.0 | 548.2 | 699.0 |

TABLE 2b for FIG. 5

| | M5 | M6 | M7 |
|---|---|---|---|
| Maximum angle of incidence [°] | 77.6 | 24.1 | 6.2 |
| Minimum angle of incidence [°] | 68.9 | 3.0 | 1.1 |
| Extent of the reflection surface | 695.4 | 679.2 | 1138.3 |
| in the x-direction [mm] | | | |
| Extent of the reflection surface | 265.6 | 236.5 | 1116.3 |
| in the y-direction [mm] | | | |
| Maximum mirror diameter [mm] | 695.5 | 679.2 | 1138.3 |

TABLE 3a for FIG. 5

| | | | Tilt about the x-axis |
|---|---|---|---|
| | y-distance [mm] | z-distance [mm] | [degrees] |
| Object field | 3841.367302 | 2298.271500 | −11.313866 |
| M1 | 3472.067232 | 1106.730472 | 230.067622 |
| M2 | 2715.380121 | 715.250226 | 14.289855 |
| M3 | 2016.558570 | 700.313827 | 170.019689 |
| M4 | 737.855663 | 1195.906402 | 2.923211 |
| M5 | 469.216382 | 1058.841885 | 42.545793 |
| M6 | −138.006550 | 84.809786 | −18.449873 |
| M7 | 0.000000 | 1675.064709 | −2.479927 |
| Stop (AS) | −74.346569 | 818.366260 | −4.959854 |
| Image field | 0.000000 | 0.000000 | −0.000000 |

TABLE 3b for FIG. 5

| | | Tilt about the y- | Tilt about the z-axis |
|---|---|---|---|
| | y-distance [mm] | axis [degrees] | [degrees] |
| Object field | 3841.367302 | −0.00 | −0.00 |
| M1 | 3472.067232 | 0.00 | −0.00 |
| M2 | 2715.380121 | 180.00 | 0.00 |
| M3 | 2016.558570 | 0.00 | −0.00 |
| M4 | 737.855663 | 0.00 | 180.00 |
| M5 | 469.216382 | 0.00 | −0.00 |
| M6 | −138.006550 | 180.00 | 0.00 |
| M7 | 0.000000 | 0.00 | −0.00 |
| Stop (AS) | −74.346569 | 180.00 | 0.00 |
| Image field | 0.000000 | 0.00 | −0.00 |

TABLE 4 for FIG. 5

| M1 | |
|---|---|
| RDX | −4085.603569 |
| RDY | −3649.056731 |
| CCX | 0.000000 |
| CCY | 0.000000 |
| x**i * y**j | Coefficient |
| x**2 * y**1 | −1.273025e−08 |
| x**0 * y**3 | −3.438227e−08 |
| x**4 * y**0 | −7.769419e−12 |
| x**2 * y**2 | 6.297340e−12 |
| x**0 * y**4 | −5.158602e−11 |
| x**4 * y**1 | −9.899688e−15 |
| x**2 * y**3 | 4.146723e−14 |
| x**0 * y**5 | −8.153198e−14 |
| x**6 * y**0 | 7.191049e−17 |
| x**4 * y**2 | 5.559633e−17 |
| x**2 * y**4 | −3.573411e−17 |
| x**0 * y**6 | −6.130103e−17 |
| x**6 * y**1 | 6.589301e−19 |
| x**4 * y**3 | 1.139784e−19 |
| x**2 * y**5 | 2.779372e−19 |
| x**0 * y**7 | −2.413345e−19 |
| x**8 * y**0 | −6.681059e−21 |
| x**6 * y**2 | −3.092385e−21 |
| x**4 * y**4 | −5.433992e−22 |
| x**2 * y**6 | −8.815848e−24 |
| x**0 * y**8 | −2.860896e−22 |
| x**8 * y**1 | −3.046562e−23 |
| x**6 * y**3 | −1.066796e−23 |
| x**4 * y**5 | −1.432229e−24 |
| x**2 * y**7 | −1.208128e−24 |
| x**0 * y**9 | 6.098871e−25 |
| x**10 * y**0 | 2.229445e−25 |
| x**8 * y**2 | 1.683819e−25 |
| x**6 * y**4 | 6.098177e−26 |
| x**4 * y**6 | 9.162500e−27 |
| x**2 * y**8 | 1.037580e−27 |
| x**0 * y**10 | −1.470792e−27 |
| x**10 * y**1 | 5.042841e−28 |
| x**8 * y**3 | 3.053156e−28 |
| x**6 * y**5 | 2.401037e−29 |
| x**4 * y**7 | 1.019674e−29 |
| x**2 * y**9 | 1.017093e−29 |
| x**0 * y**11 | −7.473416e−30 |
| x**12 * y**0 | −2.600644e−30 |
| x**10 * y**2 | −3.383696e−30 |
| x**8 * y**4 | −1.330296e−30 |
| x**6 * y**6 | −3.069509e−31 |
| x**4 * y**8 | 3.127145e−33 |
| x**2 * y**10 | 1.162177e−32 |
| x**0 * y**12 | 3.821978e−34 |
| M2 | |
| RDX | −6983.645291 |
| RDY | 9136.794097 |
| CCX | 0.000000 |
| CCY | 0.000000 |
| x**i * y**j | Coefficient |
| x**2 * y**1 | −4.360286e−08 |
| x**0 * y**3 | 8.934124e−08 |
| x**4 * y**0 | −5.337350e−11 |
| x**2 * y**2 | 1.773389e−11 |
| x**0 * y**4 | 3.091970e−11 |
| x**4 * y**1 | 3.123146e−14 |
| x**2 * y**3 | −1.138731e−13 |
| x**0 * y**5 | 6.441166e−14 |
| x**6 * y**0 | 8.583164e−17 |
| x**4 * y**2 | −2.656928e−16 |
| x**2 * y**4 | −1.220463e−16 |
| x**0 * y**6 | −1.438273e−16 |
| x**6 * y**1 | −1.088957e−18 |
| x**4 * y**3 | −4.064829e−19 |
| x**2 * y**5 | −9.670426e−19 |
| x**0 * y**7 | 2.620221e−19 |
| x**8 * y**0 | 4.907101e−22 |
| x**6 * y**2 | −7.345245e−22 |
| x**4 * y**4 | −2.527358e−22 |
| x**2 * y**6 | 1.641948e−21 |
| x**0 * y**8 | 4.623661e−23 |
| x**8 * y**1 | 2.646394e−23 |
| x**6 * y**3 | 1.202139e−23 |
| x**4 * y**5 | −2.729489e−25 |
| x**2 * y**7 | −2.239946e−24 |
| x**0 * y**9 | −9.015879e−25 |
| x**10 * y**0 | −1.292348e−27 |
| x**8 * y**2 | 5.732097e−26 |
| x**6 * y**4 | −2.906914e−26 |
| x**4 * y**6 | −6.046095e−26 |
| x**2 * y**8 | −2.087834e−26 |
| x**0 * y**10 | −4.242941e−27 |
| x**10 * y**1 | −2.711893e−28 |
| x**8 * y**3 | −2.315435e−28 |
| x**6 * y**5 | −5.517932e−29 |
| x**4 * y**7 | 8.814392e−29 |
| x**2 * y**9 | −7.603188e−29 |
| x**0 * y**11 | 3.584957e−29 |
| x**12 * y**0 | −1.658459e−31 |
| x**10 * y**2 | −7.728240e−31 |
| x**8 * y**4 | −7.529083e−32 |
| x**6 y**6 | 7.964693e−31 |
| x**4 * y**8 | 5.501948e−32 |
| x**2 * y**10 | 2.989977e−31 |
| x**0 * y**12 | −7.200295e−32 |
| M3 | |
| RDX | 1859.305170 |
| RDY | −12549.291172 |
| CCX | 0.000000 |
| CCY | 0.000000 |
| x**i * y**j | Coefficient |
| x**2 * y**1 | −2.548489e−09 |
| x**0 * y**3 | −2.217791e−08 |
| x**4 * y**0 | 3.345135e−11 |
| x**2 * y**2 | 2.403626e−11 |
| x**0 * y**4 | 7.781153e−12 |
| x**4 * y**1 | −7.064279e−14 |
| x**2 * y**3 | −9.024852e−14 |
| x**0 * y**5 | −2.821094e−14 |
| x**6 * y**0 | −3.271710e−17 |
| x**4 * y**2 | 2.277953e−16 |
| x**2 * y**4 | 1.343676e−16 |
| x**0 * y**6 | 3.085285e−17 |
| x**6 * y**1 | 3.247774e−19 |
| x**4 * y**3 | −1.282329e−19 |
| x**2 * y**5 | −2.742670e−19 |
| x**0 * y**7 | −1.315234e−19 |
| x**8 * y**0 | −6.061351e−22 |
| x**6 * y**2 | −2.211620e−22 |
| x**4 * y**4 | 8.038324e−22 |
| x**2 * y**6 | 2.466578e−22 |
| x**0 * y**8 | −4.777765e−22 |
| x**8 * y**1 | −1.082147e−23 |
| x**6 * y**3 | −1.519695e−23 |
| x**4 * y**5 | −3.841606e−24 |
| x**2 * y**7 | 2.416449e−24 |
| x**0 * y**9 | −1.970885e−24 |
| x**10 * y**0 | 8.389623e−27 |
| x**8 * y**2 | 3.655064e−26 |
| x**6 * y**4 | 2.246442e−26 |
| x**4 * y**6 | 7.261152e−27 |
| x**2 * y**8 | 1.060631e−26 |
| x**0 * y**10 | −4.437540e−27 |
| x**10 * y**1 | 6.827519e−29 |
| x**8 * y**3 | 1.553683e−28 |
| x**6 * y**5 | 3.801003e−29 |
| x**4 * y**7 | −3.346055e−29 |
| x**2 * y**9 | 8.316397e−31 |
| x**0 * y**11 | −1.659253e−29 |
| x**12 * y**0 | 8.034968e−33 |
| x**10 * y**2 | −4.043774e−31 |
| x**8 * y**4 | −3.078403e−31 |
| x**6 * y**6 | −6.629508e−32 |
| x**4 * y**8 | 2.240967e−32 |
| x**2 * y**10 | 6.212947e−32 |
| x**0 * y**12 | −1.329679e−32 |
| M4 | |
| RDX | −3045.704722 |
| RDY | −3191.141149 |
| CCX | 0.000000 |
| CCY | 0.000000 |
| x**i * y**j | Coefficient |
| x**2 * y**1 | 1.909961e−07 |
| x**0 * y**3 | −2.464574e−07 |
| x**4 * y**0 | −4.082252e−11 |
| x**2 * y**2 | 1.755332e−10 |
| x**0 * y**4 | −6.145404e−10 |
| x**4 * y**1 | −9.112299e−15 |
| x**2 * y**3 | 6.569317e−13 |
| x**0 * y**5 | −3.070086e−12 |
| x**6 * y**0 | −1.102138e−18 |
| x**4 * y**2 | −2.476258e−17 |
| x**2 * y**4 | 3.713340e−15 |
| x**0 * y**6 | −4.308461e−15 |
| x**6 * y**1 | 9.261363e−22 |
| x**4 * y**3 | 1.922998e−19 |
| x**2 * y**5 | 1.840142e−17 |
| x**0 * y**7 | 9.363928e−19 |
| x**8 * y**0 | 6.237878e−23 |
| x**6 * y**2 | 2.687486e−23 |
| x**4 * y**4 | −7.820550e−21 |
| x**2 * y**6 | −4.194316e−20 |
| x**0 * y**8 | −1.352347e−18 |
| x**8 * y**1 | −3.868180e−25 |
| x**6 * y**3 | −1.170523e−23 |
| x**4 * y**5 | −9.142445e−23 |
| x**2 * y**7 | −2.970260e−22 |
| x**0 * y**9 | −1.046450e−20 |
| x**10 * y**0 | −1.981690e−28 |
| x**8 * y**2 | 2.294318e−27 |
| x**6 * y**4 | 5.001376e−26 |
| x**4 * y**6 | 6.914053e−25 |
| x**2 * y**8 | 2.074285e−23 |
| x**0 * y**10 | 9.919384e−23 |
| x**10 * y**1 | 1.564087e−30 |
| x**8 * y**3 | 5.536159e−29 |
| x**6 * y**5 | 5.589537e−28 |
| x**4 * y**7 | 2.599863e−28 |
| x**2 * y**9 | 7.325592e−26 |
| x**0 * y**11 | 2.791184e−25 |
| x**12 * y**0 | −9.615942e−35 |
| x**10 * y**2 | −1.243918e−32 |
| x**8 * y**4 | −2.876814e−31 |
| x**6 * y**6 | −2.212425e−30 |
| x**4 * y**8 | −6.878128e−29 |
| x**2 * y**10 | −7.927877e−28 |
| x**0 * y**12 | −5.107379e−27 |
| M5 | |
| RDX | −186175.422862 |
| RDY | 3331.273103 |
| CCX | 0.000000 |
| CCY | 0.000000 |
| x**i * y**j | Coefficient |
| x**2 * y**1 | −3.126565e−08 |
| x**0 * y**3 | 5.445123e−08 |
| x**4 * y**0 | 2.439703e−12 |
| x**2 * y**2 | −5.117207e−12 |
| x**0 * y**4 | 3.203437e−10 |
| x**4 * y**1 | 9.404469e−14 |
| x**2 * y**3 | −1.167678e−13 |
| x**0 * y**5 | 1.271221e−12 |
| x**6 * y**0 | −7.037218e−18 |
| x**4 * y**2 | −3.416487e−16 |
| x**2 * y**4 | −4.847189e−16 |
| x**0 * y**6 | 1.876668e−15 |
| x**6 * y**1 | −1.617697e−19 |
| x**4 * y**3 | −1.466163e−18 |
| x**2 * y**5 | −1.031635e−18 |
| x**0 * y**7 | 5.456301e−18 |
| x**8 * y**0 | −9.769663e−23 |
| x**6 * y**2 | −9.200464e−22 |
| x**4 * y**4 | −1.697692e−21 |
| x**2 * y**6 | 1.799961e−20 |
| x**0 * y**8 | 1.477419e−19 |
| x**8 * y**1 | 5.531172e−25 |
| x**6 * y**3 | 9.132599e−24 |
| x**4 * y**5 | 1.941099e−23 |
| x**2 * y**7 | 1.799926e−22 |
| x**0 * y**9 | 1.206099e−21 |
| x**10 * y**0 | 5.824201e−28 |
| x**8 * y**2 | 2.296743e−27 |
| x**6 * y**4 | −1.406507e−26 |
| x**4 * y**6 | 5.774789e−27 |
| x**2 * y**8 | 4.223062e−25 |
| x**0 * y**10 | 1.445489e−24 |
| x**10 * y**1 | −3.018532e−30 |
| x**8 * y**3 | −6.304825e−29 |
| x**6 * y**5 | −2.730838e−28 |
| x**4 * y**7 | 1.202038e−29 |
| x**2 * y**9 | 2.485853e−27 |
| x**0 * y**11 | −3.914385e−27 |
| x**12 * y**0 | −1.021653e−33 |
| x**10 * y**2 | −1.638816e−32 |
| x**8 * y**4 | −9.903359e−32 |
| x**6 * y**6 | −2.879879e−31 |
| x**4 * y**8 | 1.132378e−30 |
| x**2 * y**10 | 1.768791e−29 |
| x**0 * y**12 | 1.720227e−29 |
| M6 | |
| RDX | 4844.388967 |
| RDY | 1085.550019 |
| CCX | 0.000000 |
| CCY | 0.000000 |
| x**i * y**j | Coefficient |
| x**2 * y**1 | −2.125704e−07 |
| x**0 * y**3 | 7.328291e−07 |
| x**4 * y**0 | 3.917897e−11 |
| x**2 * y**2 | 2.530514e−10 |
| x**0 * y**4 | 1.417440e−09 |
| x**4 * y**1 | −1.933922e−13 |
| x**2 * y**3 | 9.969059e−14 |
| x**0 * y**5 | 6.032311e−12 |
| x**6 * y**0 | 2.384313e−17 |
| x**4 * y**2 | 3.992748e−16 |
| x**2 * y**4 | 1.055154e−15 |
| x**0 * y**6 | 2.068528e−14 |
| x**6 * y**1 | −1.402956e−19 |
| x**4 * y**3 | −8.809152e−20 |
| x**2 * y**5 | 7.894166e−18 |
| x**0 * y**7 | 8.115682e−17 |
| x**8 * y**0 | 1.791800e−23 |
| x**6 * y**2 | 3.012999e−22 |
| x**4 * y**4 | −3.766486e−21 |
| x**2 * y**6 | −2.101726e−20 |
| x**0 * y**8 | 9.702062e−20 |
| x**8 * y**1 | −3.638420e−25 |
| x**6 * y**3 | −3.856549e−24 |
| x**4 * y**5 | 9.233598e−24 |
| x**2 * y**7 | −2.011490e−22 |
| x**0 * y**9 | −1.575903e−21 |
| x**10 * y**0 | 1.383011e−29 |
| x**8 * y**2 | 3.018944e−27 |
| x**6 * y**4 | 3.110150e−26 |
| x**4 * y**6 | 4.975118e−25 |
| x**2 * y**8 | 2.385142e−24 |
| x**0 * y**10 | −2.197473e−24 |
| x**10 * y**1 | 1.498072e−31 |
| x**8 * y**3 | 9.070557e−30 |
| x**6 * y**5 | 3.594623e−29 |
| x**4 * y**7 | 6.977140e−28 |
| x**2 * y**9 | 9.890157e−27 |
| x**0 * y**11 | 2.044802e−26 |
| x**12 * y**0 | 2.674083e−35 |
| x**10 * y**2 | −4.828328e−33 |
| x**8 * y**4 | −1.129917e−31 |
| x**6 * y**6 | −1.162263e−30 |
| x**4 * y**8 | −1.072604e−29 |
| x**2 * y**10 | −2.757398e−29 |
| x**0 * y**12 | 1.361150e−29 |
| M7 | |
| RDX | −2354.999339 |
| RDY | −1820.941106 |
| CCX | 0.000000 |
| CCY | 0.000000 |
| x**i * y**j | Coefficient |
| x**2 * y**1 | 9.094834e−09 |
| x**0 * y**3 | −4.748186e−09 |
| x**4 * y**0 | −1.635019e−12 |
| x**2 * y**2 | −6.816157e−12 |
| x**0 * y**4 | −2.619961e−13 |
| x**4 * y**1 | 2.056950e−15 |
| x**2 * y**3 | 1.259552e−15 |
| x**0 * y**5 | −2.033735e−15 |
| x**6 * y**0 | −3.464273e−19 |
| x**4 * y**2 | −2.571028e−18 |
| x**2 * y**4 | −3.207578e−18 |
| x**0 * y**6 | 3.019732e−19 |
| x**6 * y**1 | 9.352336e−23 |
| x**4 * y**3 | 1.474799e−22 |
| x**2 * y**5 | 1.415053e−22 |
| x**0 * y**7 | −8.794472e−22 |
| x**8 * y**0 | −3.560971e−26 |
| x**6 * y**2 | −4.417151e−25 |
| x**4 * y**4 | −6.563779e−25 |
| x**2 * y**6 | 3.915908e−26 |
| x**0 * y**8 | 1.073214e−24 |
| x**8 * y**1 | 7.011652e−28 |
| x**6 * y**3 | 1.833210e−27 |
| x**4 * y**5 | 1.830931e−27 |
| x**2 * y**7 | 1.872865e−27 |
| x**0 * y**9 | −2.911255e−28 |
| x**10 * y**0 | −8.703567e−32 |
| x**8 * y**2 | −8.503637e−31 |
| x**6 * y**4 | −3.024299e−30 |
| x**4 * y**6 | −3.376009e−30 |
| x**2 * y**8 | −3.021966e−30 |
| x**0 * y**10 | −1.443412e−30 |
| x**10 * y**1 | −1.141488e−33 |
| x**8 * y**3 | −4.526944e−33 |
| x**6 * y**5 | −5.784917e−33 |
| x**4 * y**7 | −5.536356e−33 |
| x**2 * y**9 | −2.119949e−33 |
| x**0 * y**11 | 2.842371e−33 |
| x**12 * y**0 | 1.177480e−37 |
| x**10 * y**2 | 5.625487e−37 |
| x**8 * y**4 | 3.456288e−36 |
| x**6 * y**6 | 5.940305e−36 |
| x**4 * y**8 | 6.590123e−36 |
| x**2 * y**10 | 3.422978e−36 |
| x**0 * y**12 | −1.542815e−36 |
| x**12 * y**1 | 8.333377e−40 |
| x**10 * y**3 | 4.466346e−39 |
| x**8 * y**5 | 8.177509e−39 |
| x**6 * y**7 | 9.026110e−39 |
| x**4 * y**9 | 6.659326e−39 |
| x**2 * y**11 | −1.883548e−39 |
| x**0 * y**13 | −3.762577e−39 |
| x**14 * y**0 | −9.459026e−44 |
| x**12 * y**2 | −1.721172e−43 |
| x**10 * y**4 | −1.954920e−42 |
| x**8 * y**6 | −3.851487e−42 |
| x**6 * y**8 | −5.910161e−42 |
| x**4 * y**10 | −6.850531e−42 |
| x**2 * y**12 | 2.839030e−42 |
| x**0 * y**14 | 4.121394e−42 |

TABLE 5
for FIG. 5

| Mirrors | Reflectivity |
|---|---|
| M7 | 0.677596 |
| M6 | 0.660615 |
| M5 | 0.774072 |
| M4 | 0.697506 |
| M3 | 0.838904 |
| M2 | 0.809802 |
| M1 | 0.707723 |
| Overall transmission | 0.116199 |

TABLE 6
for FIG. 5

| x [mm] | y [mm] | z [mm] |
|---|---|---|
| −0.000 | 317.649 | 0.000 |
| −86.416 | 312.067 | 0.000 |
| −169.633 | 295.463 | 0.000 |
| −246.520 | 268.271 | 0.000 |
| −314.102 | 231.216 | 0.000 |
| −369.671 | 185.324 | 0.000 |
| −410.921 | 131.933 | 0.000 |
| −436.105 | 72.704 | 0.000 |
| −444.173 | 9.617 | 0.000 |
| −434.854 | −55.053 | 0.000 |
| −408.655 | −118.812 | 0.000 |
| −366.797 | −179.040 | 0.000 |
| −311.094 | −233.105 | 0.000 |
| −243.827 | −278.469 | 0.000 |
| −167.624 | −312.823 | 0.000 |
| −85.347 | −334.276 | 0.000 |
| 0.000 | −341.574 | 0.000 |
| 85.347 | −334.276 | 0.000 |
| 167.624 | −312.823 | 0.000 |
| 243.827 | −278.469 | 0.000 |
| 311.094 | −233.105 | 0.000 |
| 366.797 | −179.040 | 0.000 |
| 408.655 | −118.812 | 0.000 |
| 434.854 | −55.053 | 0.000 |
| 444.173 | 9.617 | 0.000 |
| 436.105 | 72.704 | 0.000 |
| 410.921 | 131.933 | 0.000 |
| 369.671 | 185.324 | 0.000 |
| 314.102 | 231.216 | 0.000 |
| 246.520 | 268.271 | 0.000 |
| 169.633 | 295.463 | 0.000 |
| 86.416 | 312.067 | 0.000 |

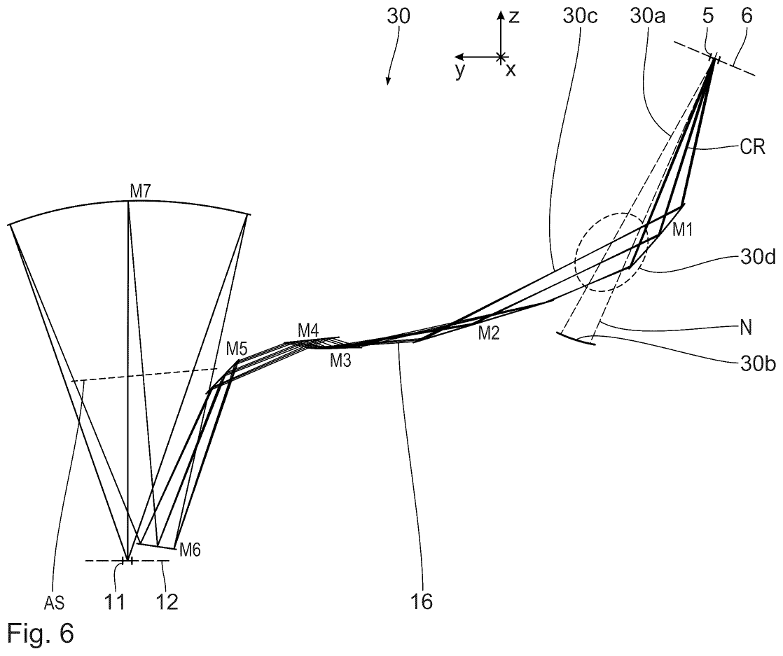

FIG. 6 shows a further embodiment of a projection optical unit or imaging optical unit 30, which can be used in the projection exposure apparatus 1 instead of the projection optical unit 10 of the embodiment according to FIG. 2. Components and functions corresponding to those which have already been explained above in conjunction with FIGS. 1 to 5, and in particular in conjunction with FIGS. 2 to 5, are denoted by the same reference signs and are not discussed in detail again.

The basic mirror structure of the projection optical unit 30 corresponds to that of the projection optical unit 28 according to FIG. 4, especially in relation to the arrangement of the GI mirrors. A substantial difference is that, in the projection optical unit 30 according to FIG. 6, the penultimate NI mirror M6 is arranged on the same side as the other mirrors M1 to M5 in relation to the partial beam path section between the last mirror M7 and the image field 11. Hence, the projection optical unit 30 according to FIG. 6 does not have a crossing region corresponding to the crossing region 25 present in the projection optical units according to FIGS. 2 to 5.

In the case of the projection optical unit 30, a chief ray CR of a central field point starting at the object field 5 runs, in relation to a normal N of this central field point of the object field 5 and initially in relation to a plane (xN) formed by each normal N and an axis parallel to the x-axis, in a different half-space, which extends to the right of the normals N in FIG. 6, in comparison with the arrangement positions of the mirrors M2ff.

This leads to, firstly, an illumination/imaging beam path section 30a between a last component 30b of the illumination optical unit 4, indicated as a mirror in FIG. 6, and the object field 5 and, secondly, an illumination/imaging light beam path section 30c between the first two mirrors M1 and M2 of the projection optical unit 30 crossing in a crossing region 30d. Thus, the illumination/imaging beam path section 30a between one of the last components (component 30b) of the illumination optical unit 4 and the object field 5 and an illumination/imaging beam path section 30c between the object field 5 and one of the first components (beam path section between mirrors M1 and M2) of the imaging optical unit 30 cross in the crossing region 30d.

Additionally, in comparison with the other mirrors M2ff, the mirror M1 is located in the other half-space in relation to this xN-plane.

The following tables summarize parameters and the optical design of the projection optical unit 30. In terms of their structure, these tables correspond to those already explained above in conjunction with FIG. 2.

TABLE 1
for FIG. 6

| | |
|---|---|
| Wavelength | 13.5 nm |
| Image-side aperture | 0.33 |
| β | −4.00 |
| Chief ray angle | 5.99° |
| Étendue | 7.08 mm² |
| Mean wavefront aberration RMS | 18.59 mλ |
| Overall transmission | 11.63% |
| Position of the entrance pupil (x) | 25190.57 mm |
| Position of the entrance pupil (y) | 2205.50 mm |
| Object-image offset in the y-direction | 2680.38 mm |
| Image field size (x) | 26 mm |
| Image field size (y) | 2.5 mm |
| Distance between M6 and image plane | 53 mm |
| Distance between the object plane and | 2300.01 mm |
| image plane | |
| Tilt between the object and | 22.8° |
| Image plane | |
| Installation space cuboid | (1112 × 3074 × 1591) mm |

TABLE 2a
for FIG. 6

| | M1 | M2 | M3 | M4 |
|---|---|---|---|---|
| Maximum angle of incidence [°] | 67.7 | 87.7 | 82.1 | 73.9 |
| Minimum angle of incidence [°] | 64.3 | 78.5 | 69.2 | 66.1 |
| Extent of the reflection surface | 242.4 | 343.8 | 423.5 | 450.9 |
| in the x-direction [mm] | | | | |
| Extent of the reflection surface | 368.7 | 646.2 | 233.0 | 231.6 |
| in the y-direction [mm] | | | | |
| Maximum mirror diameter [mm] | 382.4 | 653.6 | 458.4 | 489.6 |

TABLE 2b
for FIG. 6

| | M5 | M6 | M7 |
|---|---|---|---|
| Maximum angle of incidence [°] | 70.9 | 23.9 | 5.2 |
| Minimum angle of incidence [°] | 62.5 | 2.7 | 1.4 |
| Extent of the reflection surface | 472.4 | 519.3 | 1111.7 |
| in the x-direction [mm] | | | |
| Extent of the reflection surface | 198.4 | 162.6 | 1089.7 |
| in the y-direction [mm] | | | |
| Maximum mirror diameter [mm] | 483.2 | 519.3 | 1112.8 |

TABLE 3a
for FIG. 6

| | y-distance | z-distance | Tilt about the x-axis |
|---|---|---|---|
| | [mm] | [mm] | [degrees] |
| Object field | 2680.382457 | 2300.010557 | −22.847106 |
| M1 | 2434.840558 | 1489.891018 | 229.558257 |
| M2 | 1595.484414 | 1080.904466 | 16.965774 |
| M3 | 902.729497 | 984.119557 | 176.716845 |
| M4 | 783.883818 | 1014.898592 | 4.717944 |
| M5 | 469.669777 | 875.293664 | 45.797711 |
| M6 | 138.399446 | 69.980230 | −8.664747 |
| M7 | 0.000000 | 1642.220303 | 2.515302 |
| Stop (AS) | 70.332781 | 843.228538 | 5.030604 |
| Image field | 0.000000 | 0.000000 | −0.000000 |

TABLE 3b
for FIG. 6

| | y-distance | Tilt about the y- | Tilt about the |
|---|---|---|---|
| | [mm] | axis [degrees] | z-axis [degrees] |
| Object field | 2680.382457 | −0.00 | −0.00 |
| M1 | 2434.840558 | 0.00 | −0.00 |
| M2 | 1595.484414 | 180.00 | 0.00 |
| M3 | 902.729497 | 0.00 | −0.00 |
| M4 | 783.883818 | 0.00 | 180.00 |
| M5 | 469.669777 | 0.00 | −0.00 |
| M6 | 138.399446 | 180.00 | 0.00 |
| M7 | 0.000000 | 0.00 | −0.00 |
| Stop (AS) | 70.332781 | 180.00 | 0.00 |
| Image field | 0.000000 | 0.00 | −0.00 |

TABLE 4
for FIG. 6

| | |
|---|---|
| M1 | |
| RDX | −3313.530346 |
| RDY | −3181.111962 |
| CCX | 0.000000 |
| CCY | 0.000000 |
| x**i * y**j | Coefficient |
| x**2 * y**1 | −7.582118e−08 |
| x**0 * y**3 | 1.625021e−09 |
| x**4 * y**0 | −1.844386e−11 |
| x**2 * y**2 | −4.310334e−11 |
| x**0 * y**4 | −9.714942e−11 |
| x**4 * y**1 | −3.570331e−14 |
| x**2 * y**3 | −9.535826e−14 |
| x**0 * y**5 | −6.946156e−14 |
| x**6 * y**0 | 1.427766e−16 |
| x**4 * y**2 | 9.074740e−19 |
| x**2 * y**4 | −1.557101e−16 |
| x**0 * y**6 | −3.163685e−16 |
| x**6 * y**1 | 4.630309e−19 |
| x**4 * y**3 | 1.653687e−20 |
| x**2 * y**5 | −1.097765e−19 |
| x**0 * y**7 | −3.591852e−19 |
| x**8 * y**0 | −2.007583e−20 |
| x**6 * y**2 | −1.184243e−20 |
| x**4 * y**4 | −3.010348e−21 |
| x**2 * y**6 | 4.439019e−22 |
| x**0 * y**8 | −6.041298e−22 |
| x**8 * y**1 | −4.030616e−23 |
| x**6 * y**3 | −1.803344e−23 |
| x**4 * y**5 | −6.243843e−24 |
| x**2 * y**7 | −9.461471e−24 |
| x**0 * y**9 | −6.156404e−25 |
| x**10 * y**0 | 1.186587e−24 |
| x**8 * y**2 | 1.071000e−24 |
| x**6 * y**4 | 4.337366e−25 |
| x**4 * y**6 | 7.270102e−26 |
| x**2 * y**8 | −1.451449e−26 |
| x**0 * y**10 | −3.559025e−26 |
| x**10 * y**1 | 1.213805e−27 |
| x**8 * y**3 | 7.439958e−28 |
| x**6 * y**5 | 3.600159e−28 |
| x**4 * y**7 | 1.074975e−28 |
| x**2 * y**9 | 1.744898e−28 |
| x**0 * y**11 | −7.590744e−29 |
| x**12 * y**0 | −2.604785e−29 |
| x**10 * y**2 | −3.202548e−29 |
| x**8 * y**4 | −1.500887e−29 |
| x**6 * y**6 | −6.020977e−30 |
| x**4 * y**8 | −4.322349e−31 |
| x**2 * y**10 | −1.243331e−31 |
| x**0 * y**12 | 2.757043e−31 |
| M2 | |
| RDX | 11992.468309 |
| RDY | −20981.241416 |
| CCX | 0.000000 |
| CCY | 0.000000 |
| x**i * y**j | Coefficient |
| x**2 * y**1 | −7.852900e−08 |
| x**0 * y**3 | 2.854992e−08 |
| x**4 * y**0 | −2.562820e−11 |
| x**2 * y**2 | 1.198367e−10 |
| x**0 * y**4 | −2.890190e−11 |
| x**4 * y**1 | 1.244608e−13 |
| x**2 * y**3 | −1.221425e−13 |
| x**0 * y**5 | 4.905688e−14 |
| x**6 * y**0 | 4.066450e−17 |
| x**4 * y**2 | −8.766498e−17 |
| x**2 * y**4 | 2.943755e−16 |
| x**0 * y**6 | −7.331828e−17 |
| x**6 * y**1 | −1.669019e−19 |
| x**4 * y**3 | 7.788913e−19 |
| x**2 * y**5 | −5.264513e−19 |
| x**0 * y**7 | 1.100287e−19 |
| x**8 * y**0 | 6.439791e−22 |
| x**6 * y**2 | 1.723751e−22 |
| x**4 * y**4 | −8.373117e−22 |
| x**2 * y**6 | 1.084288e−21 |
| x**0 * y**8 | −9.453920e−23 |
| x**8 * y**1 | 1.869151e−24 |
| x**6 * y**3 | −8.157366e−24 |
| x**4 * y**5 | 2.156686e−24 |
| x**2 * y**7 | −4.915753e−25 |
| x**0 * y**9 | 2.551637e−25 |
| x**10 * y**0 | −9.432030e−27 |
| x**8 * y**2 | −8.658648e−27 |
| x** 6 * y**4 | −2.721782e−26 |
| x**4 * y**6 | −1.433560e−26 |
| x**2 * y**8 | 1.639116e−27 |
| x**0 * y**10 | −1.137262e−27 |
| x**10 * y**1 | −4.632339e−29 |
| x**8 * y**3 | 1.304128e−28 |
| x**6 * y**5 | 9.984786e−30 |
| x**4 * y**7 | 2.722387e−29 |
| x**2 * y**9 | −1.720073e−29 |
| x**0 * y**11 | 1.799996e−30 |
| x**12 * y**0 | −1.050270e−31 |
| x**10 * y**2 | 1.770933e−31 |
| x**8 * y**4 | 5.304236e−31 |
| x**6 * y**6 | 3.303230e−31 |
| x**4 * y**8 | −3.118373e−32 |
| x**2 * y**10 | 2.383182e−32 |
| x**0 * y**12 | −9.754717e−34 |
| M3 | |
| RDX | 1170.345602 |
| RDY | 336650.662649 |
| CCX | 0.000000 |
| CCY | 0.000000 |
| x**i * y**j | Coefficient |
| x**2 * y**1 | −1.301381e−07 |
| x**0 * y**3 | −3.108255e−07 |
| x**4 * y**0 | 9.906214e−11 |
| x**2 * y**2 | 7.910174e−10 |
| x**0 * y**4 | 7.141068e−12 |
| x**4 * y**1 | −5.206903e−13 |
| x**2 * y**3 | −1.077146e−12 |
| x**0 * y**5 | −2.187340e−12 |
| x**6 * y**0 | 2.723090e−16 |
| x**4 * y**2 | 2.325337e−15 |
| x**2 * y**4 | 9.069795e−15 |
| x**0 * y**6 | 1.056337e−15 |
| x**6 * y**1 | −1.508388e−19 |
| x**4 * y**3 | −1.704144e−17 |
| x**2 * y**5 | −1.938077e−17 |
| x**0 * y**7 | −1.679574e−17 |
| x**8 * y**0 | −1.039542e−20 |
| x**6 * y**2 | 2.047151e−20 |
| x**4 * y**4 | 5.287340e−20 |
| x**2 * y**6 | 6.171953e−20 |
| x**0 * y**8 | −1.608577e−19 |
| x**8 * y**1 | 2.050179e−23 |
| x**6 * y**3 | −1.452791e−23 |
| x**4 * y**5 | −1.418740e−22 |
| x**2 * y**7 | 7.927469e−22 |
| x**0 * y**9 | −1.699021e−21 |
| x**10 * y**0 | 8.524747e−26 |
| x**8 * y**2 | −1.455150e−25 |
| x**6 * y**4 | 4.567030e−25 |
| x**4 * y**6 | −9.761752e−25 |
| x**2 * y**8 | 1.606602e−23 |
| x**0 * y**10 | −4.033586e−24 |
| x**10 * y**1 | −3.986670e−28 |
| x**8 * y**3 | −1.124048e−27 |
| x**6 * y**5 | −8.739915e−28 |
| x**4 * y**7 | −3.840304e−26 |
| x**2 * y**9 | 3.632931e−26 |
| x**0 * y**11 | −4.475851e−26 |
| x**12 * y**0 | −9.909627e−32 |
| x**10 * y**2 | 2.589160e−30 |
| x**8 * y**4 | −8.795731e−33 |
| x**6 * y**6 | 4.908845e−29 |
| x**4 * y**8 | −1.086216e−28 |
| x**2 * y**10 | −8.754918e−29 |
| x**0 * y**12 | −2.927123e−28 |
| M4 | |
| RDX | −1622.090444 |
| RDY | −3452.298466 |
| CCX | 0.000000 |
| CCY | 0.000000 |
| x**i * y**j | Coefficient |
| x**2 * y**1 | 1.099886e−07 |
| x**0 * y**3 | 5.595355e−07 |
| x**4 * y**0 | −7.618175e−11 |
| x**2 * y**2 | −1.557522e−09 |
| x**0 * y**4 | 2.483125e−09 |
| x**4 * y**1 | 1.035235e−12 |
| x**2 * y**3 | −5.681863e−12 |
| x**0 * y**5 | 1.938797e−11 |
| x**6 * y**0 | −2.554714e−16 |
| x**4 * y**2 | 3.881774e−15 |
| x**2 * y**4 | −5.923605e−14 |
| x**0 * y**6 | 1.235608e−13 |
| x**6 * y**1 | −2.017153e−18 |
| x**4 * y**3 | 6.887264e−17 |
| x**2 * y**5 | −4.252346e−16 |
| x**0 * y**7 | 7.613249e−16 |
| x**8 * y**0 | 4.806633e−21 |
| x**6 * y**2 | −4.779376e−20 |
| x**4 * y**4 | 5.654709e−19 |
| x**2 * y**6 | −2.769703e−18 |
| x**0 * y**8 | 2.800231e−18 |
| x**8 * y**1 | 9.993880e−24 |
| x**6 * y**3 | −4.043017e−22 |
| x**4 * y**5 | 4.143514e−21 |
| x**2 * y**7 | −6.489472e−21 |
| x**0 * y**9 | −1.392074e−20 |
| x**10 * y**0 | −3.171919e−26 |
| x**8 * y**2 | 2.702425e−25 |
| x**6 * y**4 | −2.671298e−24 |
| x**4 * y**6 | −1.250227e−24 |
| x**2 * y**8 | 1.048776e−22 |
| x**0 * y**10 | −3.156565e−22 |
| x**10 * y**1 | 5.936951e−29 |
| x**8 * y**3 | 5.536071e−28 |
| x**6 * y**5 | 4.403273e−27 |
| x**4 * y**7 | −2.325259e−25 |
| x**2 * y**9 | 1.297646e−24 |
| x**0 * y**11 | −2.236824e−24 |
| x **12 * y**0 | 2.568808e−33 |
| x**10 * y**2 | −6.074430e−31 |
| x**8 * y**4 | −4.035613e−30 |
| x**6 * y**6 | 2.086143e−28 |
| x**4 * y**8 | −1.328473e−27 |
| x**2 * y**10 | 4.336924e−27 |
| x**0 * y**12 | −6.668026e−27 |
| M5 | |
| RDX | −30627.891357 |
| RDY | 6586.817156 |
| CCX | 0.000000 |
| CCY | 0.000000 |
| x**i * y**j | Coefficient |
| x**2 * y**1 | 3.064996e−07 |
| x**0 * y**3 | 1.010858e−07 |
| x**4 * y**0 | 8.330443e−11 |
| x**2 * y**2 | 6.865447e−10 |
| x**0 * y**4 | −8.960675e−10 |
| x**4 * y**1 | 7.539391e−13 |
| x**2 * y**3 | −8.282665e−13 |
| x**0 * y**5 | −7.388737e−12 |
| x**6 * y**0 | 1.966392e−16 |
| x**4 * y**2 | 1.060598e−15 |
| x**2 * y**4 | −1.906236e−14 |
| x**0 * y**6 | −4.537160e−14 |
| x**6 * y**1 | 1.844114e−18 |
| x**4 * y**3 | −1.604985e−17 |
| x**2 * y**5 | −1.457868e−16 |
| x**0 * y**7 | −2.378789e−16 |
| x**8 * y**0 | 2.009977e−22 |
| x**6 * y**2 | 2.149098e−22 |
| x**4 * y**4 | −1.888461e−19 |
| x**2 * y**6 | −7.768943e−19 |
| x**0 * y**8 | −2.464003e−19 |
| x**8 * y**1 | 1.762717e−24 |
| x**6 * y**3 | −1.681493e−22 |
| x**4 * y**5 | −1.353773e−21 |
| x**2 * y**7 | −1.221226e−21 |
| x**0 * y**9 | 1.062952e−20 |
| x**10 * y**0 | 5.774756e−28 |
| x**8 * y**2 | −6.692987e−26 |
| x**6 * y**4 | −2.100580e−24 |
| x**4 * y**6 | −7.809298e−24 |
| x**2 * y**8 | 1.328897e−23 |
| x**0 * y**10 | 1.210966e−22 |
| x**10 * y**1 | 2.019261e−29 |
| x**8 * y**3 | −2.374099e−28 |
| x**6 * y**5 | −1.096049e−26 |
| x**4 * y**7 | −4.688181e−26 |
| x**2 * y**9 | 6.695085e−26 |
| x**0 * y**11 | 7.125792e−25 |
| x**12 * y**0 | 2.597919e−32 |
| x**10 * y**2 | 3.001802e−31 |
| x**8 * y**4 | 4.824781e−30 |
| x**6 * y**6 | −4.006222e−29 |
| x**4 * y**8 | −1.755183e−28 |
| x**2 * y**10 | 1.223227e−28 |
| x**0 * y**12 | 1.882347e−27 |
| M6 | |
| RDX | 3480.131965 |
| RDY | 727.595471 |
| CCX | 0.000000 |
| CCY | 0.000000 |
| x**i * y**j | Coefficient |
| x**2 * y**1 | −2.357711e−07 |
| x**0 * y**3 | −1.723813e−08 |
| x**4 * y**0 | 8.034696e−11 |
| x**2 * y**2 | 5.315819e−10 |
| x**0 * y**4 | 4.602352e−09 |
| x**4 * y**1 | −2.845429e−13 |
| x**2 * y**3 | −6.861795e−13 |
| x**0 * y**5 | −1.008870e−11 |
| x**6 * y**0 | 6.059158e−17 |
| x**4 * y**2 | 8.612866e−16 |
| x**2 * y**4 | 1.207400e−14 |
| x**0 * y**6 | 9.517748e−14 |
| x**6 * y**1 | −3.896940e−19 |
| x**4 * y**3 | −2.593091e−18 |
| x**2 * y**5 | −5.339517e−17 |
| x**0 * y**7 | −5.038421e−16 |
| x**8 * y**0 | 2.492915e−23 |
| x**6 * y**2 | 9.517560e−22 |
| x**4 * y**4 | 2.631068e−20 |
| x**2 * y**6 | 3.987602e−19 |
| x**0 * y**8 | 4.606525e−18 |
| x**8 * y**1 | −5.383268e−25 |
| x**6 * y**3 | −6.971349e−24 |
| x**4 * y**5 | −1.348941e−22 |
| x**2 * y**7 | −1.616132e−21 |
| x**0 * y**9 | −2.364787e−22 |
| x**10 * y**0 | 4.173368e−28 |
| x**8 * y**2 | 6.927402e−27 |
| x**6 * y**4 | 1.566798e−25 |
| x**4 * y**6 | 2.576389e−24 |
| x**2 * y**8 | 2.214849e−23 |
| x**0 * y**10 | −7.880745e−23 |
| x**10 * y**1 | −9.772732e−31 |
| x**8 * y**3 | −2.762274e−29 |
| x**6 * y**5 | −1.255950e−27 |
| x**4 * y**7 | −2.906333e−26 |
| x**2 * y**9 | −3.684470e−25 |
| x**0 * y**11 | −3.136608e−24 |
| x**12 * y**0 | −1.466477e−33 |
| x**10 * y**2 | −1.728110e−32 |
| x**8 * y**4 | −4.213140e−31 |
| x**6 * y**6 | 5.716133e−30 |
| x**4 * y**8 | 1.423235e−28 |
| x**2 * y**10 | 2.478966e−27 |
| x**0 * y**12 | 2.306638e−26 |
| M7 | |
| RDX | −2104.968470 |
| RDY | −1740.817502 |
| CCX | 0.000000 |
| CCY | 0.000000 |
| x**i * y**j | Coefficient |
| x**2 * y**1 | 6.797398e−09 |
| x**0 * y**3 | 1.142756e−09 |
| x**4 * y**0 | −2.250314e−12 |
| x**2 * y**2 | −3.554959e−12 |
| x**0 * y**4 | −2.144288e−12 |
| x**4 * y**1 | 1.617744e−15 |
| x**2 * y**3 | 8.635572e−16 |
| *** 0 * y**5 | 9.742439e−16 |
| x**6 * y**0 | −6.175986e−19 |
| x**4 * y**2 | −1.946051e−18 |
| x**2 * y**4 | −1.900601e−18 |
| x**0 * y**6 | −9.709810e−19 |
| x**6 * y**1 | 3.780822e−22 |
| x**4 * y**3 | 5.083467e−22 |
| x**2 * y**5 | 5.681208e−22 |
| x**0 * y**7 | 4.825237e−22 |
| x**8 * y**0 | −9.315651e−26 |
| x**6 * y**2 | −5.448412e−25 |
| x**4 * y**4 | −8.835854e−25 |
| x**2 * y**6 | −7.462077e−25 |
| x**0 * y**8 | −7.777217e−25 |
| x**8 * y**1 | 7.004813e−29 |
| x**6 * y**3 | 1.420867e−28 |
| x**4 * y**5 | 2.498356e−28 |
| x**2 * y**7 | −1.229940e−28 |
| x**0 * y**9 | −3.616363e−28 |
| x**10 * y**0 | −1.549880e−31 |
| x**8 * y**2 | −9.094072e−31 |
| x**6 * y**4 | −2.004726e−30 |
| x**4 * y**6 | −2.019169e−30 |
| x**2 * y**8 | −1.046688e−30 |
| x**0 * y**10 | 1.512057e−30 |
| x**10 * y**1 | 9.517938e−35 |
| x**8 * y**3 | 4.112679e−34 |
| x**6 * y**5 | 4.872679e−34 |
| x**4 * y**7 | 5.046987e−34 |
| x**2 * y**9 | 2.128447e−33 |
| x**0 * y**11 | 1.552697e−33 |
| x**12 * y**0 | 1.500824e−37 |
| x**10 * y**2 | 1.631796e−36 |
| x**8 * y**4 | 5.137121e−36 |
| x**6 * y**6 | 5.471485e−36 |
| x**4 * y**8 | 3.299602e−36 |
| x**2 * y**10 | 4.525601e−37 |
| x**0 * y**12 | −3.047623e−36 |
| x**12 * y**1 | −7.062957e−41 |
| x**10 * y**3 | −3.870527e−40 |
| x**8 * y**5 | −8.221576e−40 |
| x**6 * y**7 | −4.723529e−40 |
| x**4 * y**9 | −6.414242e−40 |
| x**2 * y**11 | −3.032636e−39 |
| x**0 * y**13 | −1.970546e−39 |
| x**14 * y**0 | −7.679596e−44 |
| x**12 * y**2 | −1.625621e−42 |
| x**10 * y**4 | −6.616056e−42 |
| x**8 * y**6 | −1.050786e−41 |
| x**6 * y**8 | −7.502592e−42 |
| x**4 * y**10 | −3.474008e−42 |
| x**2 * y**12 | 6.940224e−43 |
| x**0 * y**14 | 3.053356e−42 |

TABLE 5
for FIG. 6

| Mirrors | Reflectivity |
|---|---|
| M7 | 0.677581 |
| M6 | 0.660010 |
| M5 | 0.714146 |
| M4 | 0.734803 |
| M3 | 0.838417 |
| M2 | 0.871903 |
| M1 | 0.701377 |
| Overall transmission | 0.120323 |

TABLE 6
for FIG. 6

| x [mm] | y [mm] | z [mm] |
|---|---|---|
| −0.000 | 326.867 | 0.000 |
| −81.446 | 320.449 | 0.000 |
| −159.543 | 301.465 | 0.000 |
| −231.082 | 270.713 | 0.000 |
| −293.141 | 229.471 | 0.000 |
| −343.225 | 179.443 | 0.000 |
| −379.394 | 122.674 | 0.000 |
| −400.364 | 61.464 | 0.000 |
| −405.555 | −1.720 | 0.000 |
| −395.083 | −64.359 | 0.000 |
| −369.692 | −123.984 | 0.000 |
| −330.655 | −178.309 | 0.000 |
| −279.667 | −225.338 | 0.000 |
| −218.752 | −263.457 | 0.000 |
| −150.181 | −291.468 | 0.000 |
| −76.406 | −308.572 | 0.000 |
| 0.000 | −314.321 | 0.000 |
| 76.406 | −308.572 | 0.000 |
| 150.181 | −291.468 | 0.000 |
| 218.752 | −263.457 | 0.000 |
| 279.667 | −225.338 | 0.000 |
| 330.655 | −178.309 | 0.000 |
| 369.692 | −123.984 | 0.000 |
| 395.083 | −64.359 | 0.000 |
| 405.555 | −1.720 | 0.000 |
| 400.364 | 61.464 | 0.000 |
| 379.394 | 122.674 | 0.000 |
| 343.225 | 179.443 | 0.000 |
| 293.141 | 229.471 | 0.000 |
| 231.082 | 270.713 | 0.000 |
| 159.543 | 301.465 | 0.000 |
| 81.446 | 320.449 | 0.000 |

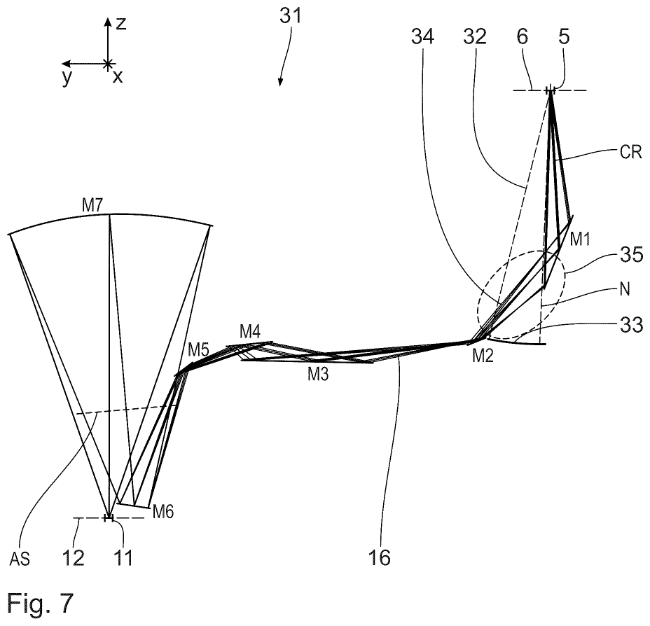

FIG. 7 shows a further embodiment of a projection optical unit or imaging optical unit 31, which can be used in the projection exposure apparatus 1 instead of the projection optical unit 10 of the embodiment according to FIG. 2. Components and functions corresponding to those which have already been explained above in conjunction with FIGS. 1 to 6, and in particular in conjunction with FIGS. 2 to 6, are denoted by the same reference signs and are not discussed in detail again.

In the case of the projection optical unit 31, a chief ray CR of a central field point starting at the object field 5 runs, in relation to a normal N of this central field point of the object field 5 and initially in relation to a plane (xN) formed by this normal N and an axis parallel to the x-axis, in a different half-space, which extends to the right of the normal N in FIG. 7, in comparison with the arrangement positions of the mirrors M2ff.

This leads to, firstly, an illumination/imaging beam path section 32 between a last component 33 of the illumination optical unit 4, indicated as a mirror in FIG. 7, and the object field 5 and, secondly, an illumination/imaging light beam path section 34 between the first two mirrors M1 and M2 of the projection optical unit 31 crossing in a crossing region 35. Thus, the illumination/imaging beam path section 32 between one of the last components (component 33) of the illumination optical unit 4 and the object field 5 and an illumination/imaging beam path section 34 between the object field 5 and one of the first components (mirrors M1 and M2) of the imaging optical unit 31 cross in the crossing region 35.

Additionally, in comparison with the other mirrors M2ff, the mirror M1 is located in the other half-space in relation to this xN-plane.

Otherwise, the projection optical unit 31 according to FIG. 7 has correspondences with the projection optical unit 28 according to FIG. 4 in relation to the arrangement of the GI mirrors M1 to M5 and correspondences with the projection optical unit 30 according to FIG. 6 in relation to the arrangement of the subsequent NI mirrors M6 and M7.

Depending on the embodiment of the above-described projection optical units, these may also have a different number of NI mirrors and/or GI mirrors, for example precisely two GI mirrors or else precisely three GI mirrors. More than two NI mirrors are also possible, for example three or four NI mirrors.

In order to produce a microstructured or nanostructured component, the projection exposure apparatus 1 is used as follows: First, the reflection mask 7 or the reticle and the substrate or the wafer 13 are provided. Subsequently, a structure on the reticle 7 is projected onto a light-sensitive layer of the wafer 13 with the aid of the projection exposure apparatus 1. Then, a microstructure or nanostructure on the wafer 13, and hence the microstructured component, is produced by developing the light-sensitive layer.

What is claimed is:

1. An imaging EUV optical unit configured to image an object field into an image field, the imaging EUV optical unit comprising:
a plurality of mirrors configured to guide EUV imaging light at a wavelength less than 30 nanometers along an imaging beam path from the object field to the image field,
wherein:
the plurality of mirrors comprises at least two normal incidence (NI) mirrors and at least two grazing incidence (GI); and
a total transmission of the plurality of mirrors is more than 10%.

2. The Imaging EUV optical unit of claim 1, wherein the last two mirrors in the imaging beam path are NI mirrors.

3. The Imaging EUV optical unit of claim 1, wherein the imaging optical unit comprises exactly two NI mirrors.

4. The Imaging EUV optical unit of claim 1, wherein the imaging optical unit comprises exactly four GI mirrors, exactly five GI mirrors, or exactly six GI mirrors.

5. The Imaging EUV optical unit of claim 1, wherein the imaging optical unit comprises a pair of successive GI mirrors which add in terms of their deflective effect.

6. The Imaging EUV optical unit of claim 1, wherein two imaging beam path sections cross in a crossing region between respectively: i) two successive mirrors and/or between a mirror; and ii) a field of the EUV optical unit.

7. The Imaging EUV optical unit of claim 6, wherein the two crossing imaging beam path sections are: i) an imaging beam path section between a mirror upstream of a penultimate NI mirror in the imaging beam path and the penultimate mirror in the imaging beam path; and ii) an imaging beam path section between the last mirror in the imaging beam path and the image field.

8. The Imaging EUV optical unit of claim 1, wherein entrance pupil in the imaging beam path upstream of the object field.

9. The Imaging EUV optical unit of claim 1, wherein the last two mirrors in the imaging beam path are NI mirrors, and the imaging optical unit comprises exactly two NI mirrors.

10. The Imaging EUV optical unit of claim 9, wherein the imaging optical unit comprises exactly four GI mirrors, exactly five GI mirrors, or exactly six GI mirrors.

11. The Imaging EUV optical unit of claim 1, wherein the last two mirrors in the imaging beam path are NI mirrors, and the imaging optical unit comprises exactly four GI mirrors, exactly five GI mirrors, or exactly six GI mirrors.

12. The Imaging EUV optical unit of claim 1, wherein the last two mirrors in the imaging beam path are NI mirrors, and the imaging optical unit comprises a pair of successive GI mirrors which add in terms of their deflective effect.

13. The Imaging EUV optical unit of claim 1, wherein the last two mirrors in the imaging beam path are NI mirrors, and two imaging beam path sections cross in a crossing region between respectively: i) two successive mirrors and/or between a mirror; and ii) a field of the EUV optical unit.

14. The Imaging EUV optical unit of claim 1, wherein the last two mirrors in the imaging beam path are NI mirrors, and the imaging EUV optical unit has an entrance pupil in the imaging beam path upstream of the object field.

15. The Imaging EUV optical unit of claim 1, wherein the imaging optical unit comprises exactly two NI mirrors, and the imaging optical unit comprises exactly four GI mirrors, exactly five GI mirrors, or exactly six GI mirrors.

16. The Imaging EUV optical unit of claim 15, wherein two imaging beam path sections cross in a crossing region between respectively: i) two successive mirrors and/or between a mirror; and ii) a field of the EUV optical unit.

17. An optical system, comprising:
an imaging optical unit according to claim 1; and
an illumination optical unit configured to illuminate the object field with imaging light.

18. The optical system of claim 17, wherein:
a first illumination/imaging beam path section is between one of the last components of the illumination optical unit and the object field;
a second illumination/imaging beam path section is between the object field and one of the first components of the imaging optical unit; and
the first and second illumination/imaging beam path sections cross in a crossing region.

19. An apparatus, comprising:
an EUV light source;
an imaging optical unit according to claim 1; and
an illumination optical unit configured to illuminate the object field with imaging light,
wherein the apparatus is a projection exposure apparatus.

20. A method of using a projection exposure apparatus comprising an illumination optical unit and an imaging optical unit, the method comprising:
using the illumination optical unit to illuminate a portion of a reticle in an object field of the imaging optical unit; and
projecting the illuminated portion of the reticle into an image field of the imaging optical unit,
wherein the imaging optical unit is an imaging optical unit according to claim 1.
